(19) United States
(12) Patent Application Publication
(10) Pub. No.: US 2026/0271201 A1
(43) Pub. Date: Sep. 10, 2026

(54) FOLDABLE ELECTRONIC DEVICE AND METHOD FOR MANUFACTURING SAME

(71) Applicant: Samsung Electronics Co., Ltd., Suwon-si (KR)

(72) Inventors: Jaedeok LIM, Suwon-si (KR); Chulhyo YOON, Suwon-si (KR); Hyein PARK, Suwon-si (KR); Jaehyoung YOU, Suwon-si (KR); Wonho LEE, Suwon-si (KR); Gyuyeong CHO, Suwon-si (KR)

(21) Appl. No.: 19/664,065

(22) Filed: Apr. 30, 2026

Related U.S. Application Data
(63) Continuation of application No. PCT/KR2024/016896, filed on Oct. 31, 2024.

(30) Foreign Application Priority Data
Oct. 31, 2023 (KR) 10-2023-0148486
Nov. 10, 2023 (KR) 10-2023-0155683

(51) Int. Cl. H05K 5/02; H05K 5/00

(52) U.S. Cl. CPC H05K 5/0226; H05K 5/0018

(57) ABSTRACT

A foldable electronic device includes a first housing, a second housing, a hinge device rotatably connecting the first housing and the second housing, a flexible display disposed across the first housing and the second housing, and a digitizer panel disposed below the flexible display, the digitizer panel including a bending pattern including multiple openings disposed at designated interval and a folding region, and wherein the digitizer panel further includes a circuit portion including at least one wiring layer and at least one insulation layer, a first shell layer disposed on an upper portion of the circuit portion, and a second shell layer disposed on a lower portion of the circuit portion.

### CROSS-REFERENCE TO RELATED APPLICATION(S)

This application is a continuation application, claiming priority under 35 U.S.C. § 365(c), of an International application No. PCT/KR2024/016896, filed on October 31, 2024, which is based on and claims the benefit of a Korean patent application number 10-2023-0148486, filed on October 31, 2023, in the Ministry of Intellectual Property (MOIP), and of a Korean patent application number 10-2023-0155683, filed on November 10, 2023, in the Ministry of Intellectual Property (MOIP), the disclosure of each of which is incorporated by reference herein in its entirety.

### BACKGROUND

### 1. Field

The disclosure relates to a foldable electronic device including a digitizer panel and a method for manufacturing the same.

### 2. Description of Related Art

An electronic device may support a pen input device (e.g., a stylus pen). A user may, e.g., input data to the electronic device using the pen input device and may perform various operations (e.g., writing or drawing) on a screen output on the display of the electronic device.

The electronic device may, e.g., receive various input data, writing, or drawing signals from an electromagnetic resonance (EMR) type pen input device. In this case, the display of the electronic device may include a digitizer for detecting a signal from the pen input device.

An EMR type pen input device includes an LC resonance circuit composed of a coil and a capacitor. A pen input device transmits a signal of a resonance frequency by an LC resonance circuit to a digitizer of an electronic device, and the electronic device detects the signal of the resonance frequency transmitted through the digitizer and performs an operation (e.g., writing or drawing) corresponding to an input of a pen.

A resonance frequency of a signal transmitted from a pen input device may vary according to changes in an inductance of a coil and a capacitance of a capacitor.

For example, in case that a pen tip of a pen input device is pressed against a display of an electronic device, a capacitance of a capacitor in the pen input device may increase, and a digitizer recognizes a pen input signal by detecting a change in a resonance frequency according to the increase in capacitance.

Similar to the change in capacitance, in case that an inductance of a coil in a pen input device changes, a resonance frequency of a signal from the pen input device may also vary. For example, in case that an inductance of a coil in a pen input device decreases due to magnetic field interference caused by a magnetic field generated from a component having magnetic force in an electronic device, a resonance frequency also decreases. In this case, even in case that there is an actual pen input and there is an increase in a capacitance of a capacitor, a decrease in an inductance of a coil may offset this, so that a digitizer may not recognize a pen input and may malfunction.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a foldable electronic device including a digitizer panel including a high-rigidity shell layer and a bending pattern and including at least one shielding layer, and a method for manufacturing the same.

Additional aspects will be set forth in part in the description which follows and, in part, will be apparent from the description, or may be learned by practice of the presented embodiments.

In accordance with an aspect of the disclosure, a foldable electronic device is provided. The foldable electronic device includes a first housing, a second housing, a hinge device rotatably connecting the first housing and the second housing, a flexible display disposed across the first housing and the second housing, and a digitizer panel disposed below the flexible display, the digitizer panel including a bending pattern including a plurality of openings disposed at a designated interval and a folding region, and wherein the digitizer panel further includes a circuit portion including at least one wiring layer and at least one insulation layer, a first shell layer disposed on an upper portion of the circuit portion, and a second shell layer disposed on a lower portion of the circuit portion.

In accordance with another aspect of the disclosure, a method for manufacturing a foldable electronic device is provided. The method includes forming a flexible display disposed across a first housing and a second housing, and forming a digitizer panel disposed below the flexible display, the digitizer panel including a folding region, and wherein the forming of the digitizer panel includes forming a circuit portion including at least one wiring layer and at least one insulation layer, forming a first shell layer disposed on an upper portion of the circuit portion and a second shell layer disposed on a lower portion of the circuit portion, and forming a bending pattern including a plurality of openings disposed at a designated interval.

According to various embodiments of the disclosure, the foldable electronic device and the method for manufacturing the same according to the disclosure minimize circuit disconnection of the digitizer panel in the folding region during folding by including a digitizer panel including a high-rigidity shell layer and a bending pattern.

Further, the foldable electronic device and the method for manufacturing the same according to the disclosure prevent corrosion of the shielding layer and enhance flatness of the display by including a digitizer panel incorporating at least one shielding layer.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment of the disclosure;

FIGS. 2A and 2B are views illustrating an unfolded state of an electronic device viewed from a front surface and a rear surface according to various embodiments of the disclosure;

FIGS. 3A and 3B are views illustrating a folded state of an electronic device viewed from a front surface and a rear surface according to various embodiments of the disclosure;

FIG. 4 is an exploded perspective view illustrating an electronic device according to an embodiment of the disclosure;

FIG. 5 is an exploded perspective view illustrating a first display according to an embodiment of the disclosure;

FIG. 6 is a partial cross-sectional view illustrating an electronic device including a digitizer panel according to an embodiment of the disclosure;

FIGS. 7A and 7B are cross-sectional views illustrating a lamination structure of a digitizer panel according to various embodiments of the disclosure;

FIG. 8 is a view illustrating a bending pattern of a digitizer panel according to an embodiment of the disclosure;

FIG. 9 is a partial cross-sectional view illustrating a folded state of an electronic device according to an embodiment of the disclosure;

FIG. 10 is a cross-sectional view illustrating an internal configuration of a digitizer panel according to an embodiment of the disclosure;

FIGS. 11A, 11B, and 11C are cross-sectional views illustrating a lamination structure of a digitizer panel according to various embodiments of the disclosure;

FIG. 12 is a perspective view illustrating a structure of at least one shielding layer according to an embodiment of the disclosure;

FIGS. 13A, 13B, 13C, and 13D are cross-sectional views illustrating a configuration of a shielding layer inside a digitizer panel according to various embodiments of the disclosure;

FIGS. 14A and 14B are cross-sectional views illustrating a configuration of a shielding layer inside a digitizer panel according to various embodiments of the disclosure;

FIGS. 15A and 15B are cross-sectional views illustrating a configuration of a shielding layer inside a digitizer panel according to various embodiments of the disclosure; and

FIG. 16 is a cross-sectional view illustrating a lamination structure of a digitizer panel according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that various embodiments of the disclosure and the terms used therein are not intended to limit the technological features set forth herein to particular embodiments and include various changes, equivalents, or replacements for a corresponding embodiment.

In this document, each of phrases such as "A or B," "at least one of A and B," "at least one of A or B," "A, B, or C," "at least one of A, B, and C," and "at least one of A, B, or C" may include any one of the items listed together in the corresponding phrase, or all possible combinations thereof.

As used herein, such terms as "1st" and "2nd," or “first” and "second" may be used to simply distinguish a corresponding component from another, and does not limit the components in other aspect (e.g., importance or order).

It is to be understood that if an element (e.g., a first element) is referred to, with or without the term “operatively” or “communicatively”, as “coupled with,” "coupled to," "connected with," or “connected to” another element (e.g., a second element), it means that the element may be coupled with the other element directly (e.g., wiredly), wirelessly, or via a third element.

It will be further understood that the terms "comprise" and/or "have,” as used herein, specify the presence of stated features, integers, steps, operations, elements, and/or components, but do not preclude the presence or addition of one or more other features, integers, steps, operations, elements, components, and/or groups thereof.

It will be understood that in case that a component is referred to as “connected to,” “coupled to”, “supported on,” or “contacting” another component, the components may be connected to, coupled to, supported on, or contact each other directly or via a third component.

Throughout the specification, in case that one component is positioned "on" another component, the first component may be positioned directly on the second component, or other component(s) may be positioned between the first and second component.

The term "and/or" may denote a combination(s) of a plurality of related components as listed or any of the components.

Hereinafter, the working principle and embodiments of the disclosure are described with reference to the accompanying drawings.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

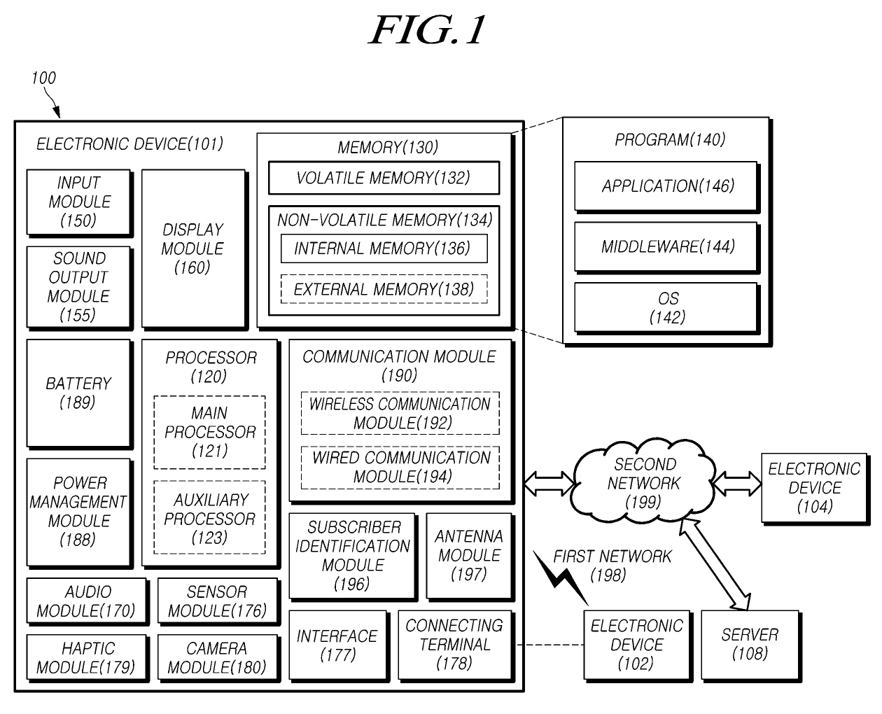

FIG. 1 is a block diagram illustrating an electronic device in a network environment according to an embodiment of the disclosure.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., the program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, in case that the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other components (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operation state (e.g., power or temperature) of the electronic device 101 or an external environmental state (e.g., the user's state), and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wiredly) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wiredly) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth^{TM}, wireless-fidelity (Wi-Fi) direct, or infrared data association (IrDA)) or a second network 199 (e.g., a long-range communication network, such as a legacy cellular network, a fifth generation (5G) network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or user plane (U-plane) latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

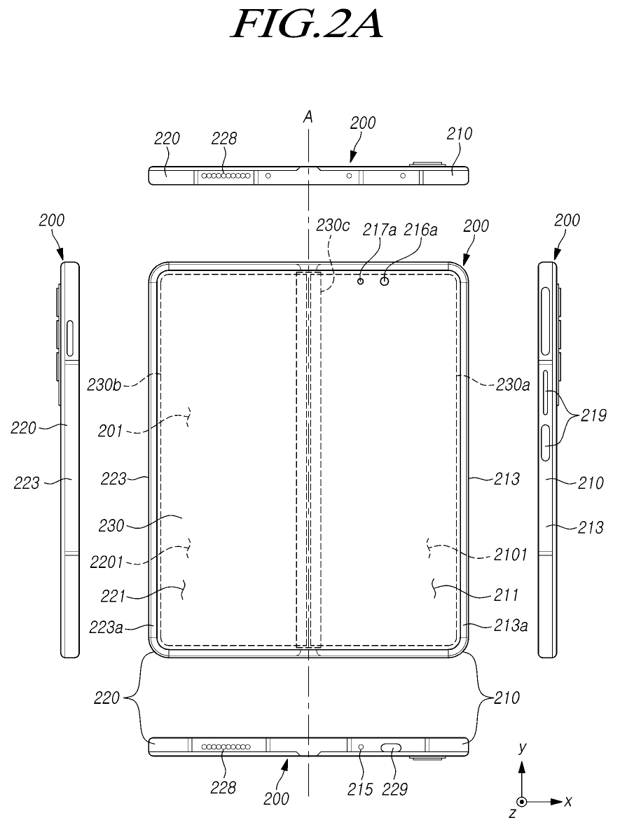

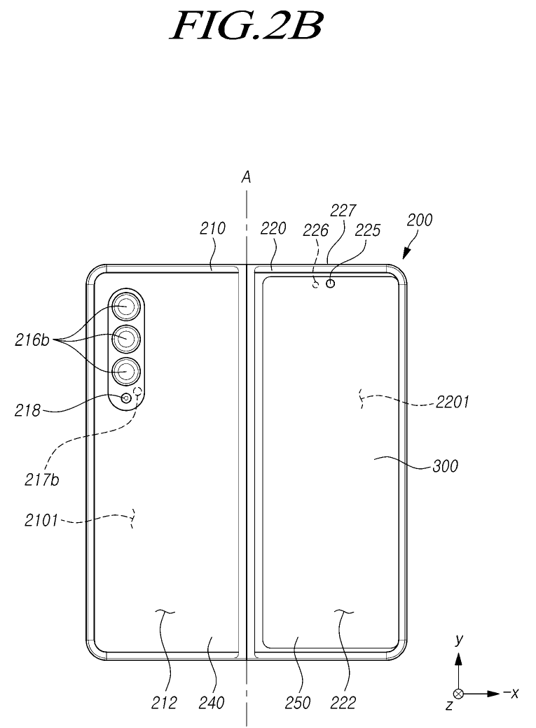

FIGS. 2A and 2B are views illustrating an unfolded state of an electronic device viewed from a front surface and a rear surface according to various embodiments of the disclosure.

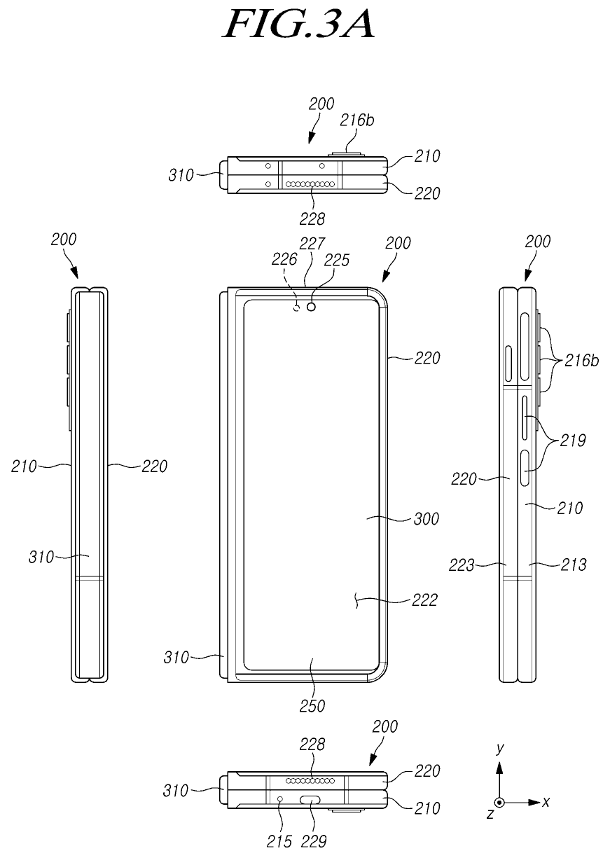

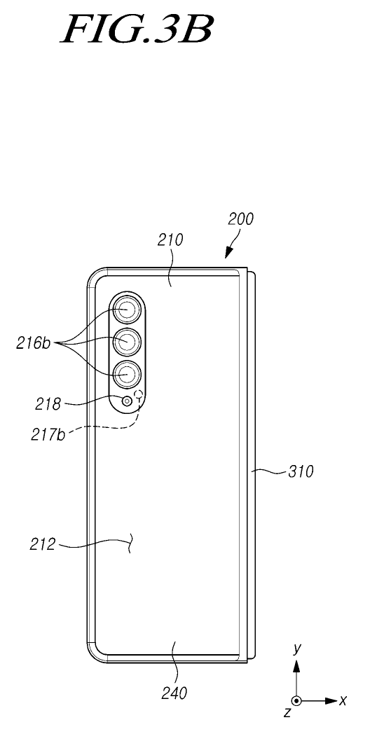

FIGS. 3A and 3B are views illustrating a folded state of an electronic device viewed from a front surface and a rear surface according to various embodiments of the disclosure.

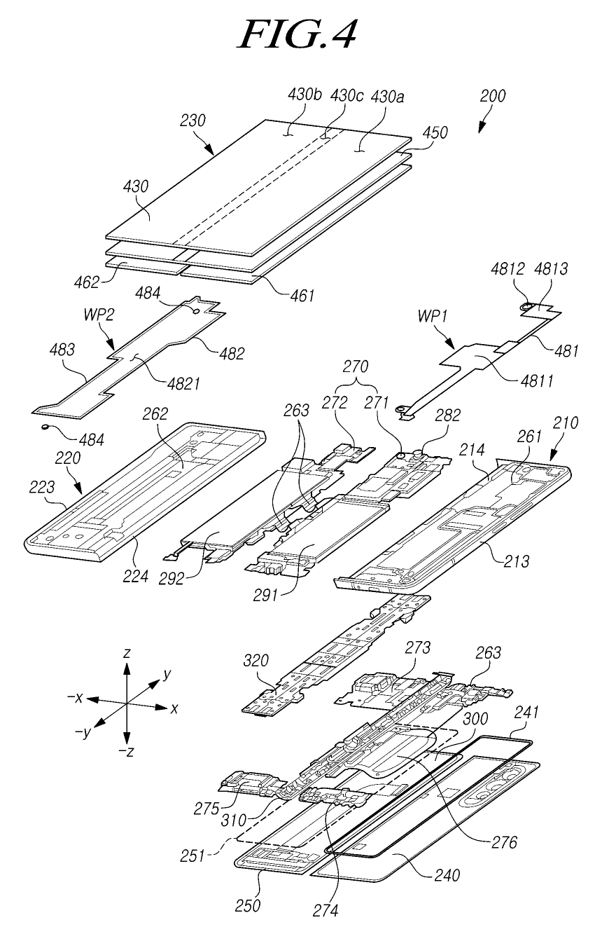

Referring to FIGS. 2A, 2B, 3A, and FIG. 3B, an electronic device 200 (e.g., the electronic device 101 of FIG. 1) may include a pair of housings 210, 220 (e.g., a foldable housing structure) rotatably coupled with respect to a folding axis A via a hinge device (e.g., the hinge device 320 of FIG. 4) (e.g., a hinge module) so as to be foldable with respect to each other, a first display 230 (e.g., a flexible display, a foldable display, or a main display) disposed through the pair of housings 210, 220, and/or a second display 300 (e.g., a sub display) disposed through the second housing 220.

According to various embodiments, at least a part of the hinge device (e.g., the hinge device 320 of FIG. 4) may be disposed not to be visible from the outside through the first housing 210 and the second housing 220, and may be disposed not to be visible from the outside through a hinge housing 310 covering a foldable portion in the unfolded state. According to an embodiment, the hinge device 320 may include a hinge module including a gear assembly including a plurality of gears and a plurality of hinge cams coupled to hinge shafts rotating through the gear assembly and performing a cam interlocking operation, and hinge plates connecting the hinge module to the first housing 210 and the second housing 220. In the document, a surface on which the first display 230 is disposed may be defined as a front surface of the electronic device 200, and a surface opposite to the front surface may be defined as a rear surface of the electronic device 200. Further, a surface surrounding a space between the front surface and the rear surface may be defined as a side surface of the electronic device 200.

According to various embodiments, the pair of housings 210, 220 may include the first housing 210 and the second housing 220 disposed to be foldable with respect to each other through the hinge device (e.g., the hinge device 320 of FIG. 4). According to an embodiment, the pair of housings 210, 220 is not limited to the form and coupling illustrated in FIGS. 2A, 2B, 3A, and FIG. 3B, and may be implemented by a combination and/or coupling of other shapes or components. According to an embodiment, the first housing 210 and the second housing 220 may be disposed on two opposite sides with respect to the folding axis A and may have a shape that is generally symmetrical with respect to the folding axis A. According to an embodiment, the first housing 210 and the second housing 220 may also be folded asymmetrically with respect to the folding axis A. According to an embodiment, the first housing 210 and the second housing 220 may have different angles or distances from each other according to whether the electronic device 200 is in an unfolded state, a folded state, or an intermediate state.

According to various embodiments, the first housing 210 may include, in the unfolded state of the electronic device 200, a first surface 211 connected to the hinge device (e.g., the hinge device 320 of FIG. 4) and disposed to face a front surface of the electronic device 200, a second surface 212 facing a direction opposite to the first surface 211, and/or a first side member 213 surrounding at least a part of a first space between the first surface 211 and the second surface 212. According to an embodiment, the second housing 220 may include, in the unfolded state of the electronic device 200, a third surface 221 connected to the hinge device (e.g., the hinge device 320 of FIG. 4) and disposed to face the front surface of the electronic device 200, a fourth surface 222 facing a direction opposite to the third surface 221, and/or a second side member 223 surrounding at least a part of a second space between the third surface 221 and the fourth surface 222. According to an embodiment, the first surface 211 may face substantially the same direction as the third surface 221 in the unfolded state, and may be at least partially faced with the third surface 221 in the folded state. According to an embodiment, the electronic device 200 may also include a recess 201 formed to receive the first display 230 through structural coupling of the first housing 210 and the second housing 220. According to an embodiment, the recess 201 may have substantially the same size as the first display 230. According to an embodiment, the first housing 210 may include a first protective frame 213a (e.g., a first decorative member) coupled to the first side member 213 and overlappingly disposed with an edge of the first display 230, in case of viewing the first display 230 from above, thereby covering the edge of the first display 230 so as not to be visible from the outside. According to an embodiment, the first protective frame 213a may also be integrally formed with the first side member 213. According to an embodiment, the second housing 220 may include a second protective frame 223a (e.g., a second decorative member) coupled to the second side member 223 and overlappingly disposed with an edge of the first display 230, in case of viewing the first display 230 from above, thereby covering the edge of the first display 230 so as not to be visible from the outside. According to an embodiment, the second protective frame 223a may also be integrally formed with the second side member 223. In some embodiments, the first protective frame 213a and the second protective frame 223a may be omitted.

According to various embodiments, the hinge housing 310 (e.g., a hinge cover) may be disposed between the first housing 210 and the second housing 220 and may be disposed to cover a part (e.g., at least one hinge module) of the hinge device (e.g., the hinge device 320 of FIG. 4) disposed in the hinge housing 310. According to an embodiment, the hinge housing 310 may be covered by a part of the first housing 210 and the second housing 220 or may be exposed to the outside according to the unfolded state, the folded state, or the intermediate state of the electronic device 200. For example, in case that the electronic device 200 is in the unfolded state, at least a part of the hinge housing 310 may be covered by the first housing 210 and the second housing 220 and may not be substantially exposed. According to an embodiment, in case that the electronic device 200 is in the folded state, at least a part of the hinge housing 310 may be exposed to the outside between the first housing 210 and the second housing 220. According to an embodiment, in case that the first housing 210 and the second housing 220 are folded with a predetermined angle in the intermediate state, the hinge housing 310 may be at least partially exposed to the outside of the electronic device 200 between the first housing 210 and the second housing 220. For example, a region in which the hinge housing 310 is exposed to the outside may be smaller than in the fully folded state. According to an embodiment, the hinge housing 310 may include a curved surface.

According to various embodiments, in case that the electronic device 200 is in the unfolded state (e.g., the state of FIGS. 1A and 2B), the first housing 210 and the second housing 220 form an angle of about 180 degrees, and a first flat region 230a, a second flat region 230b, and a folding region 230c of the first display 230 form the same plane and may be disposed to face substantially the same direction (e.g., a z-axis direction). As another embodiment, in case that the electronic device 200 is in the unfolded state, the first housing 210 may rotate at an angle of about 360 degrees with respect to the second housing 220, and may be folded in the opposite direction so that the second surface 212 and the fourth surface 222 face each other (out folding method).

According to various embodiments, in case that the electronic device 200 is in the folded state (e.g., the state of FIGS. 3A and 3B), the first surface 211 of the first housing 210 and the third surface 221 of the second housing 220 may be disposed to face each other. In this case, the first flat region 230a and the second flat region 230b of the first display 230 may form a narrow angle (e.g., a range of 0 degrees to about 10 degrees) with each other and may be disposed to face each other through the folding region 230c. According to an embodiment, at least a part of the folding region 230c may be deformed into a curved shape having a predetermined curvature. According to an embodiment, in case that the electronic device 200 is in the intermediate state, the first housing 210 and the second housing 220 may be disposed at a predetermined angle with each other. In this case, the first flat region 230a and the second flat region 230b of the first display 230 may form an angle greater than that in the folded state and smaller than that in the unfolded state, a curvature of the folding region 230c may be smaller than in the folded state and may be greater than in the unfolded state. In some embodiments, the first housing 210 and the second housing 220 may form an angle where they may stop at a designated folding angle between the folded state and the unfolded state through the hinge device (e.g., the hinge device 320 of FIG. 4) (a free stop function). In some embodiments, the first housing 210 and the second housing 220 may also be continuously operated while being pressed in a direction of unfolding or a direction of folding with respect to a designated inflection angle through the hinge device (e.g., the hinge device 320 of FIG. 4).

According to various embodiments, the electronic device 200 may include at least one of at least one display 230, 300, an input device 215, an acoustic output device 227, 228, a sensor module 217a, 217b, 226, a camera module 216a, 216b, 225, a key input device 219, an indicator (not illustrated), or a connector port 229 disposed in the first housing 210 and/or the second housing 220. In some embodiments, the electronic device 200 may omit at least one of the components or may additionally include at least one other component.

According to various embodiments, the at least one display 230, 300 may include a first display 230 (e.g., a flexible display) disposed to be supported from the first surface 211 of the first housing 210 through the hinge device (e.g., the hinge device 320 of FIG. 4) to the third surface 221 of the second housing 220, and a second display 300 disposed to be at least partially visible from the outside through the fourth surface 222 in an inner space of the second housing 220. In some embodiments, the second display 300 may also be disposed to be visible from the outside through the second surface 212 in an inner space of the first housing 210. According to an embodiment, the first display 230 may be mainly used in the unfolded state of the electronic device 200, and the second display 300 may be mainly used in the folded state of the electronic device 200. According to an embodiment, in the intermediate state, the electronic device 200 may control the first display 230 and/or the second display 300 to be usable based on a folding angle of the first housing 210 and the second housing 220.

According to various embodiments, the first display 230 may be disposed in an accommodation space formed by the pair of housings 210, 220. For example, the first display 230 may be disposed in a recess 201 formed by the pair of housings 210, 220, and in the unfolded state, may be disposed to occupy substantially most of the front surface of the electronic device 200. According to an embodiment, the first display 230 may include a flexible display in which at least a part of the region may be deformed into a flat surface or a curved surface. According to an embodiment, the first display 230 may include a first flat region 230a facing the first housing 210 and a second flat region 230b facing the second housing 220. According to an embodiment, the first display 230 may include a folding region 230c including a part of the first flat region 230a and a part of the second flat region 230b with respect to the folding axis A. According to an embodiment, at least a part of the folding region 230c may include a region corresponding to the hinge device (e.g., the hinge device 320 of FIG. 4). According to an embodiment, the division of regions of the first display 230 is merely a physical division by the pair of housings 210, 220 and the hinge device (e.g., the hinge device 320 of FIG. 4), and the first display 230 may be substantially displayed as one seamless full screen through the pair of housings 210, 220 and the hinge device (e.g., the hinge device 320 of FIG. 4). According to an embodiment, the first region 230a and the second region 230b may have a shape that is generally symmetrical with respect to the folding region 230c, or may have a partially asymmetrical shape.

According to various embodiments, the electronic device 200 may include a first rear cover 240 disposed on the second surface 212 of the first housing 210 and a second rear cover 250 disposed on the fourth surface 222 of the second housing 220. In some embodiments, at least a part of the first rear cover 240 may also be integrally formed with the first side member 213. In some embodiments, at least a part of the second rear cover 250 may also be integrally formed with the second side member 223. According to an embodiment, at least one cover of the first rear cover 240 and the second rear cover 250 may be formed of a substantially transparent plate (e.g., a glass plate including various coating layers, or a polymer plate) or an opaque plate. According to an embodiment, the first rear cover 240 may be formed by an opaque plate, such as, e.g., coated or colored glass, ceramic, polymer, metal (e.g., aluminum, stainless steel (STS), or magnesium), or a combination of at least two of the materials. According to an embodiment, the second rear cover 250 may be formed through a substantially transparent plate, such as, e.g., glass or polymer. Accordingly, the second display 300 may be disposed to be visible from the outside through the second rear cover 250 in an inner space of the second housing 220.

According to various embodiments, the input device 215 may include a microphone. In some embodiments, the input device 215 may include a plurality of microphones disposed to detect a direction of sound. According to an embodiment, the acoustic output device 227, 228 may include a speaker. According to an embodiment, the acoustic output device 227, 228 may include a receiver 227 for a call disposed through the fourth surface 222 of the second housing 220 and an external speaker 228 disposed through at least a part of the second side member 223 of the second housing 220. In some embodiments, the input device 215, the acoustic output device 227, 228, and the connector port 229 may be disposed in spaces of the first housing 210 and/or the second housing 220 and may be exposed to an external environment through at least one hole formed in the first housing 210 and/or the second housing 220. In some embodiments, the hole formed in the first housing 210 and/or the second housing 220 may be used in common for the input device 215 and the acoustic output device 227, 228. In some embodiments, the acoustic output device 227, 228 may also include a speaker (e.g., a piezo speaker) operating without a hole formed in the first housing 210 and/or the second housing 220.

According to various embodiments, the camera module 216a, 216b, 225 may include a first camera module 216a disposed on the first surface 211 of the first housing 210, a second camera module 216b disposed on the second surface 212 of the first housing 210, and/or a third camera module 225 disposed on the fourth surface 222 of the second housing 220. According to an embodiment, the electronic device 200 may include a flash 218 disposed near the second camera module 216b. According to an embodiment, the flash 218 may include, e.g., a light emitting diode or a xenon lamp. According to an embodiment, the camera modules 216a, 216b, 225 may include one or more lenses, an image sensor, and/or an image signal processor. In some embodiments, at least one camera module of the camera modules 216a, 216b, 225 may include two or more lenses (e.g., a wide-angle lens and a telephoto lens) and image sensors, and may be disposed together on any one surface of the first housing 210 and/or the second housing 220.

According to various embodiments, the sensor module 217a, 217b, 226 may generate an electrical signal or a data value corresponding to an internal operation state or an external environmental state of the electronic device 200. According to an embodiment, the sensor module 217a, 217b, 226 may include a first sensor module 217a disposed on the first surface 211 of the first housing 210, a second sensor module 217b disposed on the second surface 212 of the first housing 210, and/or a third sensor module 226 disposed on the fourth surface 222 of the second housing 220. In some embodiments, the sensor module 217a, 217b, 226 may include at least one of a gesture sensor, a grip sensor, a color sensor, an infrared (IR) sensor, an illuminance sensor, an ultrasonic sensor, an iris recognition sensor, or a distance detection sensor (e.g., a time of flight (TOF) sensor or light detection and ranging (LiDAR)).

According to various embodiments, the electronic device 200 may further include at least one of a sensor module (not illustrated), e.g., a barometric pressure sensor, a magnetic sensor, a biometric sensor, a temperature sensor, a humidity sensor, or a fingerprint recognition sensor. In some embodiments, the fingerprint recognition sensor may also be disposed through at least one side member of the first side member 213 of the first housing 210 and/or the second side member 223 of the second housing 220.

According to various embodiments, the key input device 219 may be disposed to be exposed to the outside through the first side member 213 of the first housing 210. In some embodiments, the key input device 219 may also be disposed to be exposed to the outside through the second side member 223 of the second housing 220. In some embodiments, the electronic device 200 may not include some or all of the key input devices 219, and the key input device 219 not included may be implemented in another form, such as a soft key, on the at least one display 230, 300. As another embodiment, the key input device 219 may be implemented using a pressure sensor included in the at least one display 230, 300.

According to various embodiments, the connector port 229 may include a connector (e.g., a USB connector or an interface connector port module) for transmitting/receiving power and/or data to/from an external electronic device. In some embodiments, the connector port 229 may perform a function of transmitting/receiving an audio signal to/from an external electronic device together, or may further include a separate connector port (e.g., an earjack hole) for performing a function of transmitting/receiving an audio signal.

According to various embodiments, at least one camera module 216a, 225 among the camera modules 216a, 216b, 225, at least one sensor module 217a, 226 among the sensor modules 217a, 217b, 226, and/or an indicator may be disposed to be exposed through the at least one display 230, 300. For example, the at least one camera module 216a, 225, the at least one sensor module 217a, 226, and/or the indicator may be disposed in an inner space of the at least one housing 210, 220 below a display area of the at least one display 230, 300, and may be disposed to contact an external environment through a perforated opening or a transparent region to a cover member (e.g., a window layer (not illustrated) of the first display 230 and/or the second rear cover 250). According to an embodiment, a region where the at least one display 230, 300 and the at least one camera module 216a, 225 face each other may be formed as a transmission region having a predetermined transmittance as a part of a region displaying content. According to an embodiment, the transmission region may be formed to have a transmittance in a range of about 5% to about 20%. This transmission region may include a region overlapping an effective region (e.g., a field of view region) of the at least one camera module 216a, 225 through which light for forming an image on an image sensor and generating an image passes. For example, the transmission region of the display 230, 300 may include a region having a lower pixel density than surroundings. For example, the transmission region may replace an opening. For example, the at least one camera module 216a, 225 may include an under display camera (UDC) or an under panel camera (UPC). As another embodiment, some camera modules or the sensor module 217a, 226 may also be disposed to perform the function without being visually exposed through the display. For example, a region facing the camera module 216a, 225 and/or the sensor module 217a, 226 disposed below the display 230, 300 (e.g., a display panel) may not require a perforated opening as an under display camera (UDC) structure.

FIG. 4 is an exploded perspective view illustrating an electronic device 200 according to an embodiment of the disclosure.

Referring to FIG. 4, the electronic device 200 may include a first display 230 (e.g., a flexible display), a second display 300, a hinge device 320, a pair of supporting members 261, 262, at least one board 270 (e.g., a printed circuit board (PCB)), a first housing 210, a second housing 220, a first rear cover 240, and/or a second rear cover 250.

According to various embodiments, the first display 230 may include a display panel 430 (e.g., a flexible display panel), a support plate 450 disposed below the display panel 430, and a pair of reinforcement plates 461, 462 disposed below the support plate 450. According to an embodiment, the display panel 430 may include a first panel region 430a corresponding to the first region (e.g., the first region 230a of FIG. 2A) of the first display 230, a second panel region 430b extending from the first panel region 430a and corresponding to the second region (e.g., the second region 230b of FIG. 2A) of the first display 230, and a third panel region 430c connecting the first panel region 430a and the second panel region 430b and corresponding to the folding region (e.g., the folding region 230c of FIG. 2A) of the first display 230. According to an embodiment, the support plate 450 may be disposed between the display panel 430 and the pair of supporting members 261, 262, and may be formed to have a material and a shape for providing a planar support structure for the first panel region 430a and the second panel region 430b and a flexible structure for helping flexibility in the third panel region 430c. According to an embodiment, the support plate 450 may be formed of a conductive material (e.g., metal) or a non-conductive material (e.g., polymer or fiber reinforced plastics (FRP)). According to an embodiment, the pair of reinforcement plates 461, 462 may include a first reinforcement plate 461 disposed between the support plate 450 and the pair of supporting members 261, 262 to correspond to at least a part of the first panel region 430a and the third panel region 430c, and a second reinforcement plate 462 disposed to correspond to at least a part of the second panel region 430b and the third panel region 430c. According to an embodiment, the pair of reinforcement plates 461, 462 may be formed of a metal material (e.g., steel use stainless (SUS)), thereby helping a ground connection structure and rigidity reinforcement for the first display 230.

According to various embodiments, the second display 300 may be disposed in a space between the second housing 220 and the second rear cover 250. According to an embodiment, the second display 300 may be disposed to be visible from the outside through substantially the entire area of the second rear cover 250 in a space between the second housing 220 and the second rear cover 250.

According to various embodiments, at least a part of the first supporting member 261 may be foldably coupled to the second supporting member 262 through the hinge device 320. According to an embodiment, the electronic device 200 may include at least one wiring member 263 (e.g., a flexible printed circuit board (FPCB)) disposed from at least a part of the first supporting member 261 across the hinge device 320 to a part of the second supporting member 262. According to an embodiment, the first supporting member 261 may be disposed in a manner extending from or structurally coupled to the first side member 213. According to an embodiment, the electronic device 200 may include a first space (e.g., the first space 2101 of FIG. 2A) provided through the first supporting member 261 and the first rear cover 240. According to an embodiment, the first housing 210 (e.g., a first housing structure) may be configured through coupling of the first side member 213, the first supporting member 261, and the first rear cover 240. According to an embodiment, the second supporting member 262 may be disposed in a manner extending from or structurally coupled to the second side member 223. According to an embodiment, the electronic device 200 may include a second space (e.g., the second space 2201 of FIG. 2A) provided through the second supporting member 262 and the second rear cover 250. According to an embodiment, the second housing 220 (e.g., a second housing structure) may be configured through coupling of the second side member 223, the second supporting member 262, and the second rear cover 250. According to an embodiment, the at least one wiring member 263 and/or at least a part of the hinge device 320 may be disposed to be supported through at least a part of the pair of supporting members 261, 262. According to an embodiment, the at least one wiring member 263 may be disposed in a direction (e.g., an x-axis direction) crossing the first supporting member 261 and the second supporting member 262. According to an embodiment, the at least one wiring member 263 may be disposed in a direction (e.g., an x-axis direction) substantially perpendicular to the folding axis (e.g., a y-axis or the folding axis A of FIG. 2A).

According to various embodiments, the at least one board 270 may include a first board 271 disposed in the first space 2101 and a second board 272 disposed in the second space 2201. According to an embodiment, the first board 271 and the second board 272 may include a plurality of electronic components disposed to implement various functions of the electronic device 200. According to an embodiment, the first board 271 and the second board 272 may be electrically connected through the at least one wiring member 263.

According to various embodiments, the electronic device 200 may include at least one battery 291, 292. According to an embodiment, the at least one battery 291, 292 may include a first battery 291 disposed in the first space 2101 of the first housing 210 and electrically connected to the first board 271, and a second battery disposed in the second space 2201 of the second housing 220 and electrically connected to the second board 272. According to an embodiment, the first supporting member 261 and the second supporting member 262 may further include at least one swelling hole for the first battery 291 and the second battery 292.

According to various embodiments, the first housing 210 may include a first rotation support surface 214, and the second housing 220 may include a second rotation support surface 224 corresponding to the first rotation support surface 214. According to an embodiment, the first rotation support surface 214 and the second rotation support surface 224 may include a curved surface corresponding to (naturally connected to) a curved outer surface of the hinge housing 310. According to an embodiment, the first rotation support surface 214 and the second rotation support surface 224 may cover the hinge housing 310, thereby not exposing the hinge housing 310 to the rear surface of the electronic device 200 or exposing only a part thereof, in case that the electronic device 200 is in the unfolded state. According to an embodiment, the first rotation support surface 214 and the second rotation support surface 224 may rotate along the curved outer surface of the hinge housing 310, thereby at least partially exposing the hinge housing 310 to the rear surface of the electronic device 200, in case that the electronic device 200 is in the folded state.

According to various embodiments, the electronic device 200 may include at least one antenna 276 disposed in the first space 2101. According to an embodiment, the at least one antenna 276 may be disposed between the first battery 291 and the first rear cover 240 in the first space 2101. According to an embodiment, the at least one antenna 276 may include, e.g., a near field communication (NFC) antenna, a wireless charging antenna, and/or a magnetic secure transmission (MST) antenna. According to an embodiment, the at least one antenna 276 may, e.g., perform short-range communication with an external device or wirelessly transmit/receive power required for charging. In some embodiments, an antenna structure may be formed by at least a part of the first side member 213 or the second side member 223 and/or a part of the first supporting member 261 and the second supporting member 262 or a combination thereof.

According to various embodiments, the electronic device 200 may further include at least one electronic component assembly 274, 275 and/or additional supporting members 263, 273 disposed in the first space 2101 and/or the second space 2201. For example, the at least one electronic component assembly may include an interface connector port assembly 274 or a speaker assembly 275.

According to various embodiments, the electronic device 101 may include a first waterproof structure WP1 disposed between the first reinforcement plate 461 and the first supporting member 261 and a second waterproof structure WP2 disposed between the second reinforcement plate 462 and the second supporting member 262. According to an embodiment, the first waterproof structure WP1 may include a first waterproofing member 481 disposed such that at least one first waterproof space 4811, 4812, 4813 is formed between the first reinforcement plate 461 and the first supporting member 261. According to an embodiment, the second waterproof structure WP2 may include a second waterproofing member 482, a third waterproofing member 483, and a fourth waterproofing member 484 disposed such that at least one second waterproof space 4821 is formed between the second reinforcement plate 462 and the second supporting member 262. According to an embodiment, the fourth waterproofing member 484 may be disposed to connect stepped and spaced apart spaces of the second waterproofing member 482 and the third waterproofing member 483.

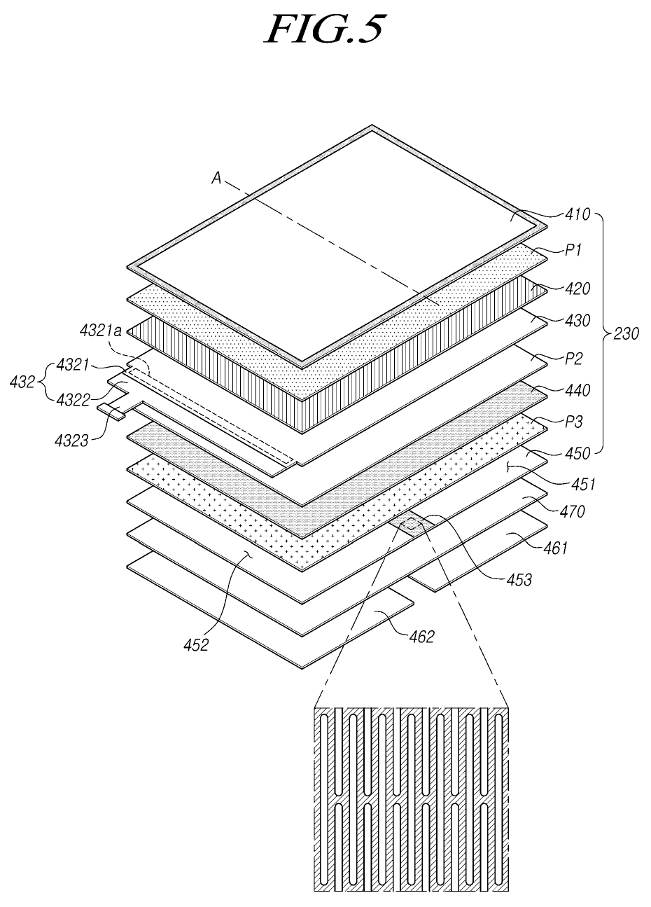

According to various embodiments, the at least one first waterproof space 4811 may be disposed to receive a through path of an FPCB connection portion as a wiring structure for connecting an electronic component disposed between the first reinforcement plate 461 and the first supporting member 262 to the first space 2101 through the first waterproofing member 481. According to an embodiment, the at least one second waterproof space 4821 may be disposed to receive a through path of an FPCB connection portion as a wiring structure for connecting an electronic component disposed between the second reinforcement plate 462 and the second supporting member 262 to the second space 2201 through the second waterproofing member 482, the third waterproofing member 483, and the fourth waterproofing member 484. According to an embodiment, the at least one first waterproof space 4812, 4813 may receive a region corresponding to at least one electronic component (e.g., a camera module or a sensor module) disposed to be supported by the first supporting member 261. According to an embodiment, the at least one second waterproof space 4821 may receive at least a part of a bending portion (e.g., the bending portion 432 of FIG. 5) folded to a rear surface of the first display 230. For example, the at least one second waterproof space 4821 may be disposed to surround at least a part of a bending portion 432 extending from the display panel (e.g., the display panel 430 of FIG. 5) of the first display 230 and folded to a rear surface. Accordingly, a control circuit (e.g., the control circuit 4321a of FIG. 5) and a plurality of electrical elements (not illustrated) disposed in the bending portion 432 may be disposed in the at least one second waterproof space 4821, thereby being protected from external moisture and/or foreign objects.

According to various embodiments, the electronic device 200 may include a waterproofing tape 241 disposed between the first rear cover 240 and the first housing 210. According to an embodiment, the electronic device 200 may include a bonding member 251 disposed between the second rear cover 250 and the second housing 220. In some embodiments, the bonding member 251 may also be disposed between the second display 300 and the second housing 220. In some embodiments, the waterproofing tape 241 may be replaced with the bonding member 251, and the bonding member 251 may be replaced with the waterproofing tape 241.

The electronic device 200 according to an embodiment of the disclosure may include at least one waterproof structure WP1, WP2 in which the at least one waterproofing member 481, 482, 483, 484 is disposed between the first supporting member 261 of the first housing 210 and the first reinforcement plate 461 and/or between the second supporting member 262 of the second housing 220 and the second reinforcement plate 462, thereby reducing a phenomenon in which the first display 230 is damaged through the waterproofing member in case that the first display 230 is separated from the housings 210, 220 for maintenance of the electronic device 200, and since the at least one waterproofing member 481, 482, 483, 484 is disposed to avoid a rear surface of the first display 230, external visibility may be enhanced and may help to secure surface quality.

FIG. 5 is an exploded perspective view illustrating a first display according to an embodiment of the disclosure.

Hereinafter, the first display is referred to as a "flexible display."

A flexible display (e.g., the first display 230 of FIG. 4) according to embodiments of the disclosure may include an unbreakable (UB) type organic light emitting diode (OLED) display (e.g., a curved display). However, the flexible display is not limited thereto, and the flexible display 230 may also include a flat type display of an on cell touch active matrix organic light emitting diode (OCTA) type.

Referring to FIG. 5, the flexible display 230 may include a window layer 410, a polarizer layer (POL) 420 (e.g., a polarizer film), a display panel 430, a polymer layer 440, a support plate 450, and reinforcement plates 461, 462 sequentially disposed on a rear surface (e.g., a -z-axis direction) of the window layer 410. In an embodiment, the flexible display 230 may also include a digitizer panel 470 disposed between the support plate 450 and the reinforcement plates 461, 462. In another embodiment, the digitizer panel 470 may also be disposed between the polymer layer 440 and the support plate 450.

According to various embodiments, the window layer 410 may include a glass layer. According to an embodiment, the window layer 410 may include an ultra-thin glass (UTG). In some embodiments, the window layer 410 may also include a polymer. In this case, the window layer 410 may include polyethylene terephthalate (PET) or polyimide (PI). In some embodiments, the window layer 410 may also be disposed in a plurality of layers to include a glass layer and a polymer.

According to various embodiments, the window layer 410, the polarizer layer 420, the display panel 430, the polymer layer 440, and the support plate 450 may be disposed to cross at least a part of the first surface (e.g., the first surface 211 of FIG. 2A) of the first housing (e.g., the first housing 210 of FIG. 2A) and the third surface (e.g., the third surface 221 of FIG. 2A) of the second housing (e.g., the second housing 220 of FIG. 2A). According to an embodiment, the reinforcement plates 461, 462 may include a first reinforcement plate 461 corresponding to the first housing (e.g., the first housing 210 of FIG. 2A) and a second reinforcement plate 462 corresponding to the second housing (e.g., the second housing 220 of FIG. 2A). According to an embodiment, the reinforcement plates 461, 462 may provide rigidity for the flexible display 230 and may be used as a ground for preventing malfunction of the flexible display 230. According to an embodiment, the reinforcement plates 461, 462 may be formed of a metal material. According to an embodiment, the reinforcement plates 461, 462 may be formed of SUS or AL. According to an embodiment, the window layer 410, the polarizer layer 420, the display panel 430, the polymer layer 440, the support plate 450, and the reinforcement plates 461, 462 may be attached to each other through an adhesive P1, P2, P3 (or an adhesive agent). For example, the adhesive P1, P2, P3 may include at least one of an optically clear adhesive (OCA), a pressure sensitive adhesive (PSA), a thermoreactive adhesive, a general adhesive, or a double-sided tape.

According to various embodiments, the display panel 430 may include a plurality of pixels and a wiring structure (e.g., an electrode pattern). According to an embodiment, the polarizer layer 420 may selectively pass light generated from a light source of the display panel 430 and vibrating in a predetermined direction. According to an embodiment, the display panel 430 and the polarizer layer 420 may be integrally formed. According to an embodiment, the flexible display 230 may also include a touch panel (not illustrated).

According to various embodiments, the polymer layer 440 may be disposed below the display panel 430, thereby providing a dark background for securing visibility of the display panel 430 and may be formed of a cushioning material for a buffering effect. In some embodiments, the polymer layer 440 may be removed or disposed below the support plate 450 for waterproofing of the flexible display 230.

According to various embodiments, the support plate 450 may provide bending characteristics to the flexible display 230. For example, the support plate 450 may be formed of a non-metallic thin plate material, such as fiber reinforced plastics (FRP) (e.g., carbon fiber reinforced plastics (CFRP) or glass fiber reinforced plastics (GFRP)) having a rigid characteristic for supporting the display panel 430. According to an embodiment, the support plate 450 may include a first flat portion 451 corresponding to the first housing (e.g., the first housing 210 of FIG. 2A), a second flat portion 452 corresponding to the second housing (e.g., the second housing 220 of FIG. 2A), and a bending portion 453 (a flexible portion or a bending portion) connecting the first flat portion 451 and the second flat portion 452. According to an embodiment, the bending portion 453 may include a plurality of openings 4531 disposed at a designated interval. According to an embodiment, bending characteristics of the bending portion 453 may be determined through at least one of a size, a shape, or an arrangement density of at least some openings among the plurality of openings 4531. In some embodiments, the support plate 450 may also be formed of a metal material such as steel use stainless (SUS) (e.g., stainless steel (STS)), Cu, Al, or metal CLAD (e.g., a lamination member in which SUS and Al are alternately disposed). In this case, the support plate 450 may also have a plurality of openings formed through an entire area so that a detection operation of the digitizer panel 470 disposed below is induced. According to an embodiment, the support plate 450 may help reinforce rigidity of the electronic device (e.g., the electronic device 200 of FIG. 2A), may shield surrounding noise, and may be used to dissipate heat emitted from surrounding heat emitting components.

According to various embodiments, the display 230 may include a digitizer panel 470 as a detection member disposed below the support plate 450 and receiving an input of an electronic pen (e.g., a stylus). According to an embodiment, the digitizer panel 470 may include coil members disposed on a dielectric substrate (e.g., a dielectric film or a dielectric sheet) to detect an electromagnetic induction type resonance frequency applied from an electronic pen. According to an embodiment, the digitizer panel 470 may include a flat region including a first flat region facing the first housing 210 and a second flat region facing the second housing 220, and a folding region facing the hinge device 320. According to an embodiment, the digitizer panel 470 may be electrically connected to boards (e.g., the boards 271, 272 of FIG. 4) of the electronic device (e.g., the electronic device 200 of FIG. 4) through an FPCB connection portion, thereby performing a function of a digitizer.

According to various embodiments, the flexible display 230 may also include at least one functional member (not illustrated) disposed between the polymer layer 440 and the support plate 450 or below the support plate 450. According to an embodiment, the functional member may include a graphite sheet for heat dissipation, an added display, a force touch FPCB, a fingerprint sensor FPCB, a communication antenna radiator, or a conductive/non-conductive tape. According to an embodiment, the functional member may also be individually disposed in the first housing (e.g., the first housing 210 of FIG. 2A) and the second housing (e.g., the second housing 220 of FIG. 2A) in case that the functional member is not bendable. According to an embodiment, the functional member may be disposed from the first housing (e.g., the first housing 210 of FIG. 2A) through the hinge device (e.g., the hinge device 320 of FIG. 4) to at least a part of the second housing (e.g., the second housing 220 of FIG. 2A) in case that the functional member is bendable.

According to various embodiments, the flexible display 230 may include a bending portion 432 disposed in a manner of being folded from the display panel 430 to at least a part of a region of a rear surface (e.g., a -z-axis direction) of the flexible display 230. According to an embodiment, the bending portion 432 may include an extension 4321 extending from the display panel 430 and including a control circuit 4321a, and a flexible board 4322 electrically connected to the extension 4321 and including a plurality of electrical elements. According to an embodiment, the control circuit 4321a may include a display driver IC (DDI) or a touch display driver IC (TDDI) mounted on the extension 4321 having an electrical wiring structure. According to an embodiment, the bending portion 432 may include a chip on panel (or chip on plastic) (COP) structure in which the control circuit 4321a is directly disposed on the extension 4321. In some embodiments, the bending portion 432 may also include a chip on film (COF) structure in which the control circuit 4321a is mounted on a separate connection film (not illustrated) connecting the extension 4321 and the flexible board 4322. According to an embodiment, the flexible display 230 may include a plurality of electrical elements (not illustrated) disposed on the flexible board 4322. According to an embodiment, the flexible display 230 may include an FPCB connection portion 4323 extending from the flexible board 4322 and electrically connected to a board (e.g., the second board 272 of FIG. 4) of the electronic device (e.g., the electronic device 200 of FIG. 4). According to an embodiment, the plurality of electrical elements may include passive elements such as a touch IC, a flash memory for a display, an ESD prevention diode, a pressure sensor, a fingerprint sensor, or a decap. As another embodiment, in case that the bending portion 432 is disposed in a region facing the first housing (e.g., the first housing 210 of FIG. 2A) of the flexible display 230, the FPCB connection portion 4323 may also be electrically connected to another board (e.g., the second board 271 of FIG. 4) of the electronic device (e.g., the electronic device 200 of FIG. 4).

According to embodiments of the disclosure, an electronic device (e.g., the electronic device 200 of FIG. 4) may include a digitizer panel including a high-rigidity shell layer and a bending pattern and including at least one shielding layer. For example, the electronic device may minimize circuit disconnection of the digitizer panel in the folding region during folding by including a digitizer panel including a high-rigidity shell layer and a bending pattern. For example, the electronic device may prevent corrosion of the shielding layer and may enhance flatness of the display by including a digitizer panel incorporating at least one shielding layer.

Hereinafter, a digitizer panel 470 included in the electronic device is described in detail.

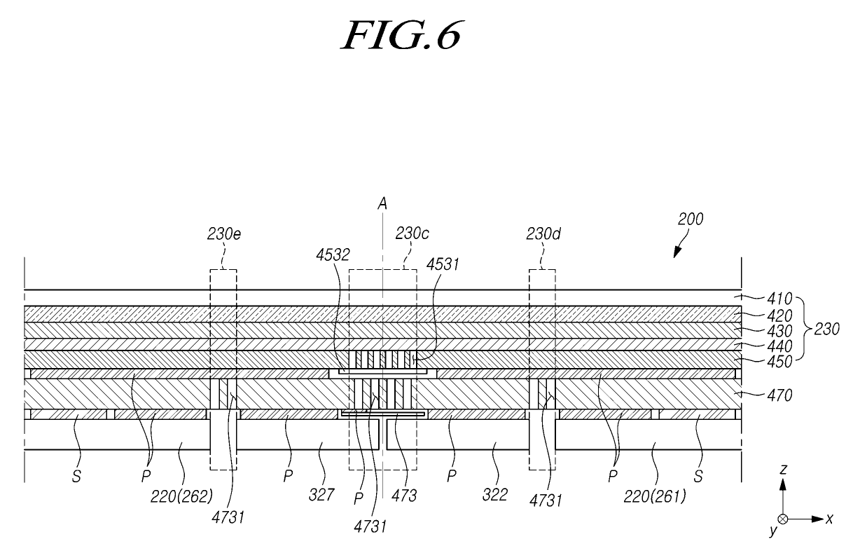

FIG. 6 is a partial cross-sectional view illustrating an electronic device 200 including a digitizer panel 470 according to an embodiment of the disclosure.

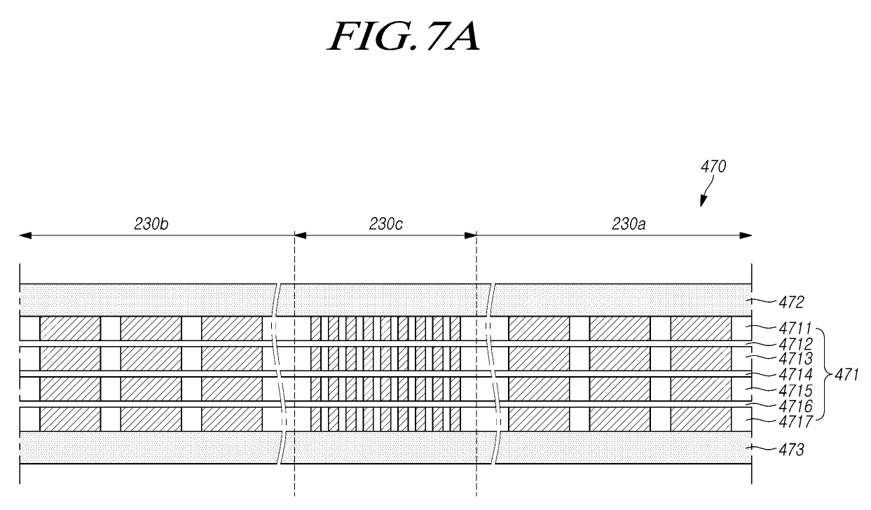

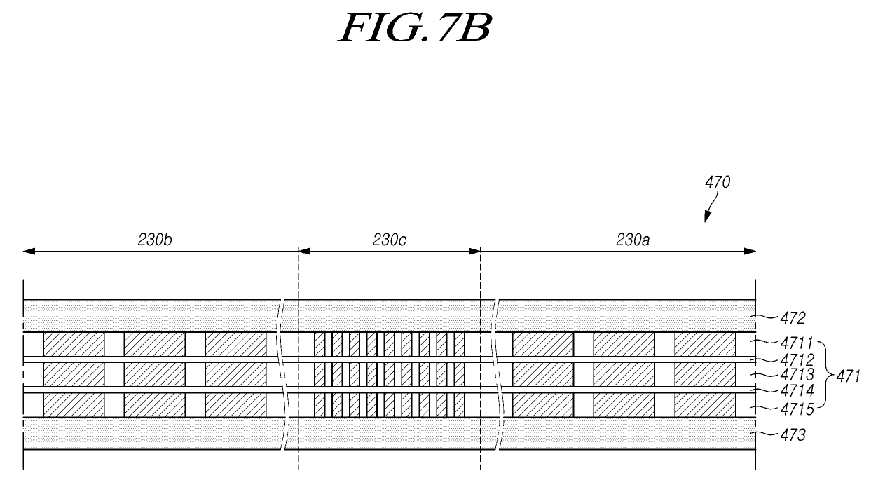

FIGS. 7A and 7B are cross-sectional views illustrating a lamination structure of a digitizer panel 470 according to various embodiments of the disclosure.

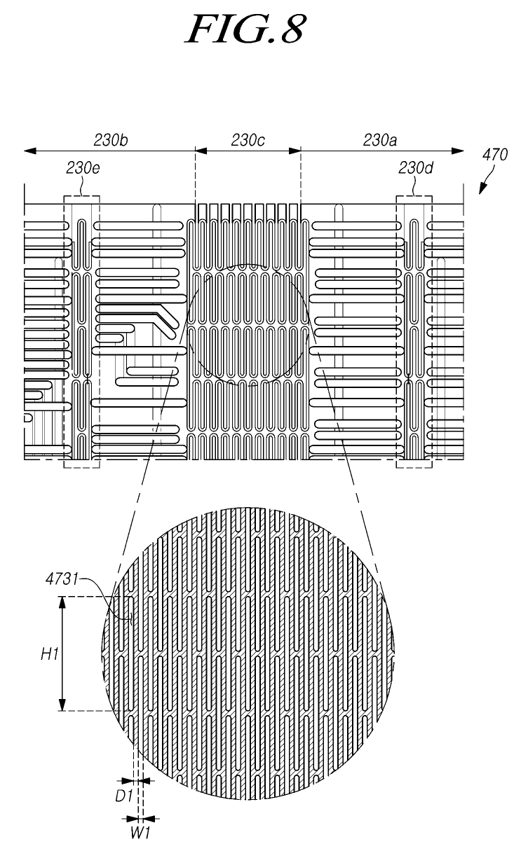

FIG. 8 is a view illustrating a bending pattern 4731 of a digitizer panel 470 according to an embodiment of the disclosure.

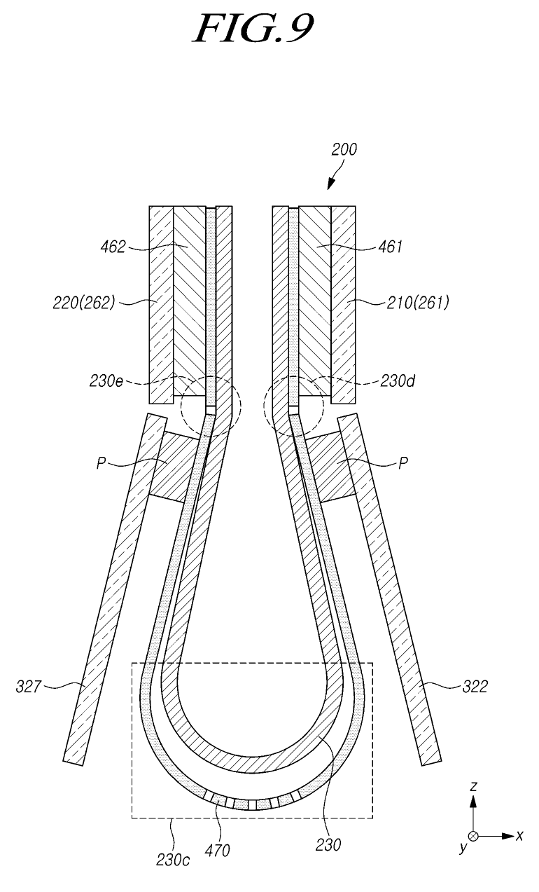

FIG. 9 is a partial cross-sectional view illustrating a folded state of an electronic device 200 according to an embodiment of the disclosure.

Referring to FIGS. 6, 7A, and 7B, the electronic device 200 may include a digitizer panel 470 disposed below the flexible display 230. The digitizer panel 470 may include a flat region including a first flat region 230a facing the first housing 210 and a second flat region 230b facing the second housing 220, and a folding region 230c facing the hinge device 320. For example, the digitizer panel 470 may be implemented as an integrated digitizer panel 470 including a flat region and a folding region 230c.

According to an embodiment, the integrated digitizer panel 470 may include a bending pattern 4731 including at least one opening and/or at least one recess disposed to have a designated interval and a designated arrangement density for enhancing flexibility of the flexible display 230. For example, the bending pattern 4731 may include a plurality of openings disposed at a designated interval. For example, the bending pattern 4731 may be formed in at least one region of the flat region and the folding region 230c of the integrated digitizer panel 470.

According to an embodiment, the digitizer panel 470 may include a circuit portion 471 including at least one wiring layer and at least one insulation layer, a first shell layer 472 disposed on an upper portion of the circuit portion 471, and a second shell layer 473 disposed on a lower portion of the circuit portion 471. The circuit portion 471 may include N wiring layers, where N is a natural number equal to or greater than 2. For example, as illustrated in FIG. 7A, the circuit portion 471 may include a first wiring layer 4711, a second wiring layer 4713, a third wiring layer 4715, and a fourth wiring layer 4717. Here, at least one insulation layer (e.g., a first insulation layer 4712, a second insulation layer 4714, a third insulation layer 4716) may be disposed between each wiring layer. For example, as illustrated in FIG. 7B, the circuit portion 471 may include a first wiring layer 4711, a second wiring layer 4713, and a third wiring layer 4715. Here, at least one insulation layer (e.g., a first insulation layer 4712, a second insulation layer 4714) may be disposed between each wiring layer.

The first shell layer 472 may be formed on an upper portion of the circuit portion 471. The second shell layer 473 may be formed on a lower portion of the circuit portion 471. The first shell layer 472 and the second shell layer 473 may be formed of a non-metallic thin plate material such as fiber reinforced plastics (FRP) having a rigid characteristic. For example, the first shell layer 472 and the second shell layer 473 may include at least one of a carbon fiber reinforced plastics (CFRP) sheet and a glass fiber reinforced plastics (GFRP) sheet. For example, as illustrated in FIG. 9, by disposing the first shell layer 472 and the second shell layer 473 having a rigid characteristic in the form surrounding the circuit portion 471, in case that the electronic device 200 is folded, the digitizer panel 470 may be bent in the folding region 230c while forming a larger radius than the flexible display 230. Accordingly, during folding, disconnection of the circuit portion 471 of the digitizer panel 470 may be minimized.

The folding region 230c of the digitizer panel 470 may include a bending section. Further, the flat region of the digitizer panel 470 may include a reverse bending section. For example, the first flat region 230a may include a first reverse bending section 230d, and the second flat region 230b may include a second reverse bending section 230e. According to an embodiment, the bending pattern 4731 of the integrated digitizer panel 470 may be formed in a bending section corresponding to the folding region 230c, as illustrated in FIG. 8, in case of viewing the flexible display 230 from above. According to an embodiment, the bending pattern 4731 of the integrated digitizer panel 470 may be formed in a portion corresponding to the reverse bending section 230d, 230e of the flat region 230a, 230b, in case of viewing the flexible display 230 from above.

According to an embodiment, the plurality of openings of the bending pattern 4731 may have a shape, an arrangement structure, and an arrangement density capable of determining bending characteristics of the flexible display 230. Each of the plurality of openings may be formed as a slit having a predetermined length and width along the folding axis (the A axis) and having a predetermined interval with respect to each other. For example, as illustrated in FIG. 8, the bending section may include the bending pattern 4731 including the plurality of openings having a first length H1 along the folding axis, a first width W1 smaller than the first length H1, and disposed at a first interval D1. For example, the reverse bending section may include the bending pattern 4731 including the plurality of openings having a second length along the folding axis, a second width smaller than the second length, and disposed at a second interval. For example, the second length may be the same as the first length, the second width may be the same as the first width W1, and the second interval may be the same as the first interval.

According to an embodiment, the digitizer panel 470 may provide elasticity and bending characteristics through the bending pattern 4731 while inducing the digitizer panel 470 to detect a wireless signal of an external electronic pen. For example, as illustrated in FIG. 9, the bending pattern 4731 may be disposed to have a zigzag wave shape while proceeding in a direction perpendicular to the folding axis A in at least one of the bending section and the reverse bending section of the digitizer panel 470, thereby helping to enhance bending characteristics of the flexible display 230. For example, the first length of the plurality of openings may have a length of 15 times to 30 times the first interval. For example, the first width W1 of the plurality of openings may have a length of 1.2 times to 1.5 times the first interval. However, the shape and size of the bending pattern 4731 are not limited thereto and may be varied.

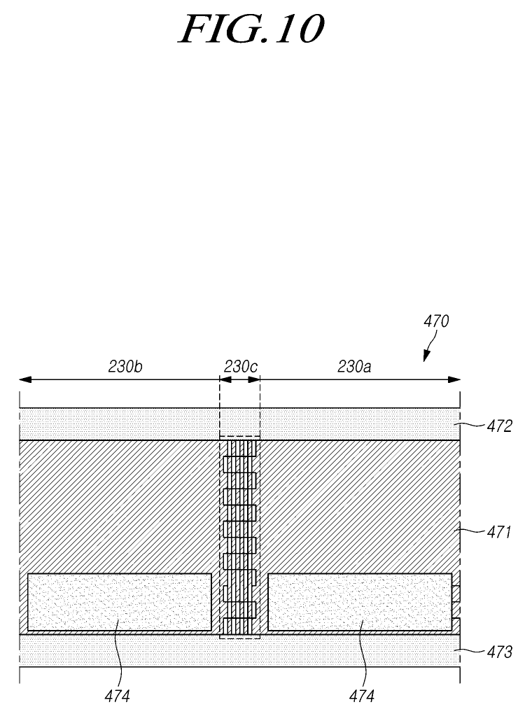

FIG. 10 is a cross-sectional view illustrating an internal configuration of a digitizer panel 470 according to an embodiment of the disclosure.

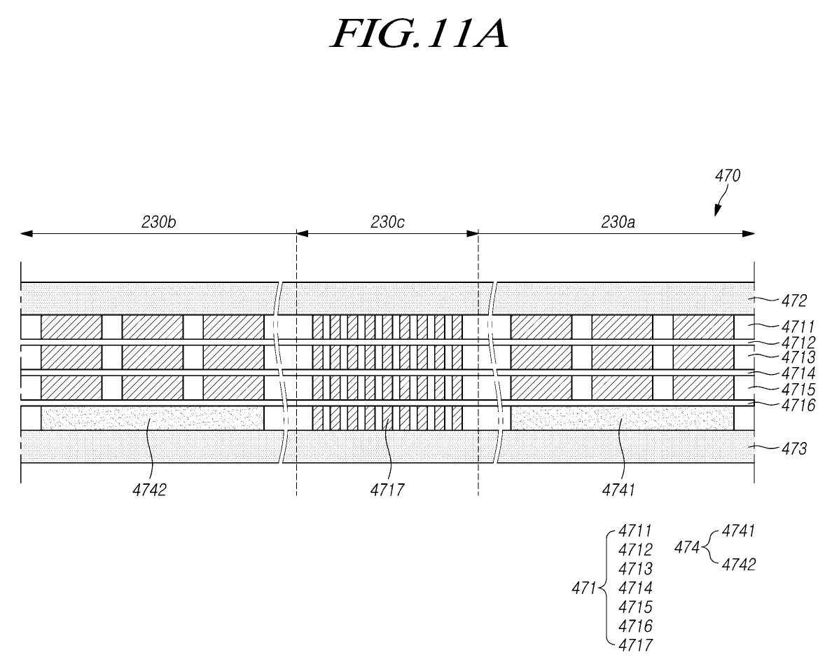

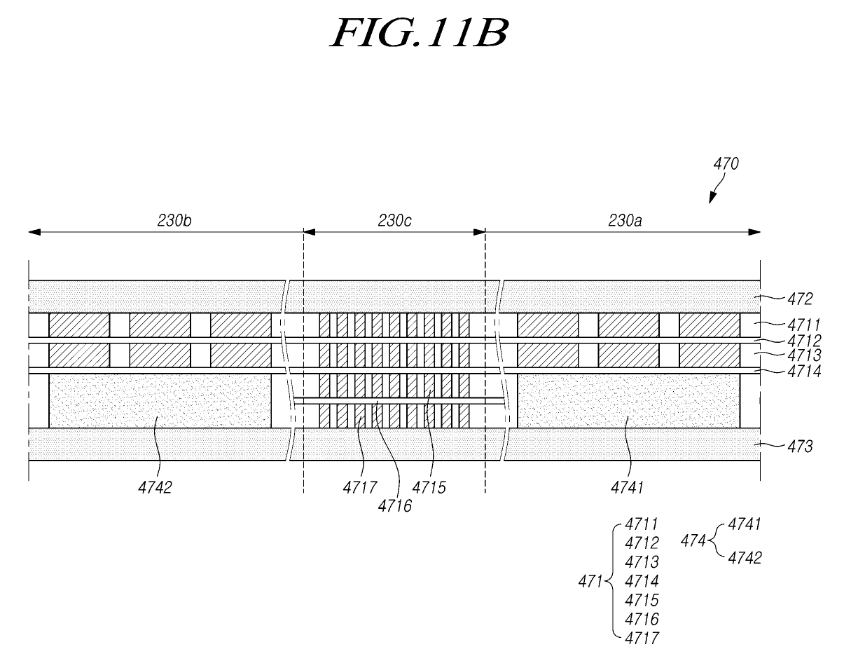

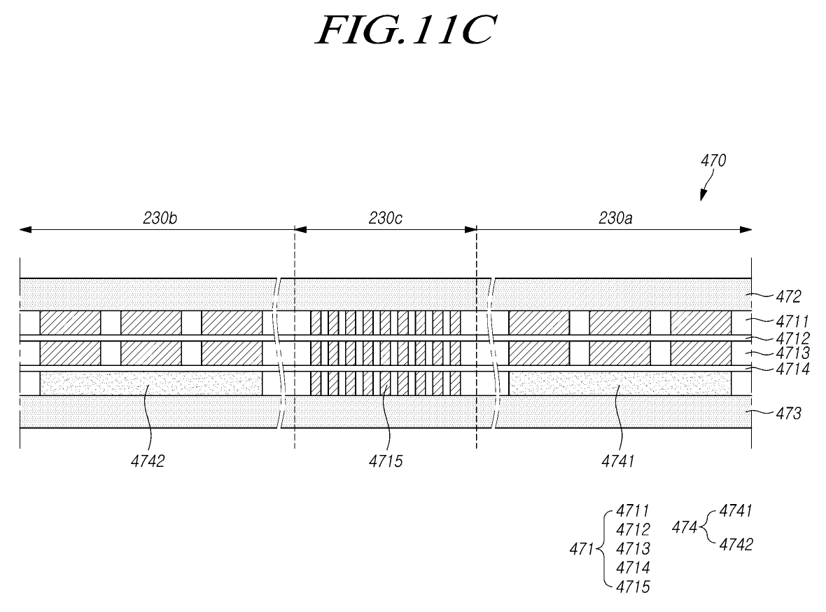

FIGS. 11A, 11B, and 11C are cross-sectional views illustrating a lamination structure of a digitizer panel 470 according to various embodiments of the disclosure.

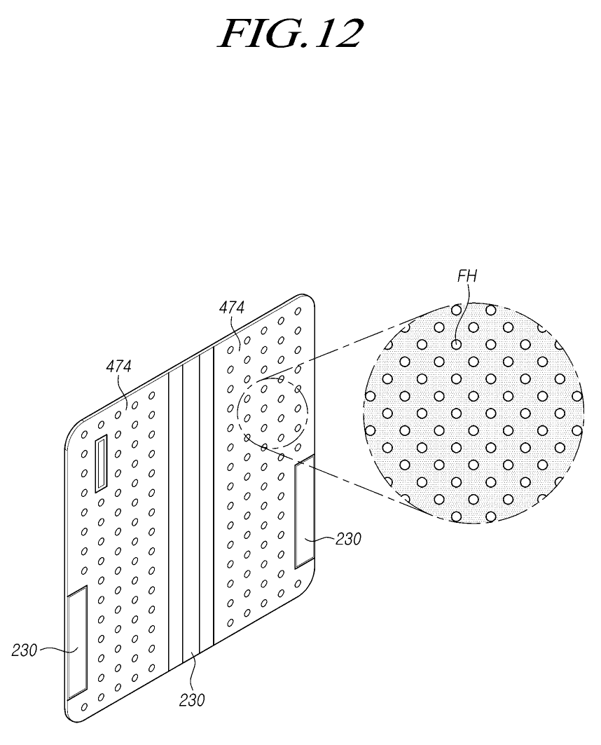

FIG. 12 is a perspective view illustrating a structure of at least one shielding layer 474 according to an embodiment of the disclosure.

Referring to FIG. 10, the digitizer panel 470 may include a flat region including a first flat region 230a facing the first housing 210 and a second flat region 230b facing the second housing 220, and a folding region 230c facing the hinge device 320. The digitizer panel 470 may include a circuit portion 471 including at least one wiring layer and at least one insulation layer, a first shell layer 472 disposed on an upper portion of the circuit portion 471, and a second shell layer 473 disposed on a lower portion of the circuit portion 471. The at least one wiring layer may include a plurality of lines. For example, the folding region 230c of the circuit portion 471 may include N wiring layers, where N is a natural number equal to or greater than 2. For example, the flat region of the circuit portion 471 may include M wiring layers, where M is a natural number less than N, and at least one shielding layer 474.

Referring to FIG. 11A, the folding region 230c of the circuit portion 471 may include four wiring layers, and the flat region of the circuit portion 471 may include three wiring layers and at least one shielding layer 474. For example, the at least one shielding layer 474 of the flat region may be formed in the same layer as the fourth wiring layer 4717 of the folding region 230c. For example, the shielding layer 474 may include a first shielding layer 4741 of the first flat region 230a formed in the same layer as the fourth wiring layer 4717 and a second shielding layer 4742 of the second flat region 230b formed in the same layer as the fourth wiring layer 4717.

Referring to FIG. 11B, the folding region 230c of the circuit portion 471 may include four wiring layers, and the flat region of the circuit portion 471 may include two wiring layers and at least one shielding layer 474. For example, the at least one shielding layer 474 of the flat region may be formed in a layer corresponding to the third wiring layer 4715 and the fourth wiring layer 4717 of the folding region 230c. For example, the shielding layer 474 may include a first shielding layer 4741 of the first flat region 230a formed in a layer corresponding to the third wiring layer 4715 and the fourth wiring layer 4717, and a second shielding layer 4742 of the second flat region 230b formed in a layer corresponding to the third wiring layer 4715 and the fourth wiring layer 4717.

Referring to FIG. 11C, the folding region 230c of the circuit portion 471 may include three wiring layers, and the flat region of the circuit portion 471 may include two wiring layers and at least one shielding layer 474. For example, the at least one shielding layer 474 of the flat region may be formed in the same layer as the third wiring layer 4715 of the folding region 230c. For example, the shielding layer 474 may include a first shielding layer 4741 of the first flat region 230a formed in the same layer as the third wiring layer 4715 and a second shielding layer 4742 of the second flat region 230b formed in the same layer as the third wiring layer 4715. The digitizer panel 470 of the disclosure may prevent corrosion of the shielding layer 474 and may enhance flatness of the display by including, inside the flat region, at least one shielding layer 474 corresponding to the wiring layer of the folding region 230c.

Referring to FIG. 12, the shielding layer 474 may include a predetermined region corresponding to the flexible display 230. The shielding layer 474 may include a plurality of filling holes FH disposed at a constant interval and into which resin is introduced. For example, in case of laminating the first shell layer 472 and the second shell layer 473 on an upper portion and a lower portion of the circuit portion 471, resin is introduced through the plurality of filling holes FH, thereby firmly fixing each component of the digitizer panel 470 and minimizing delamination of the shielding layer 474. For example, the filling hole FH may have a diameter of between 0.1 mm and 5 mm so that the introduction of resin is smooth.

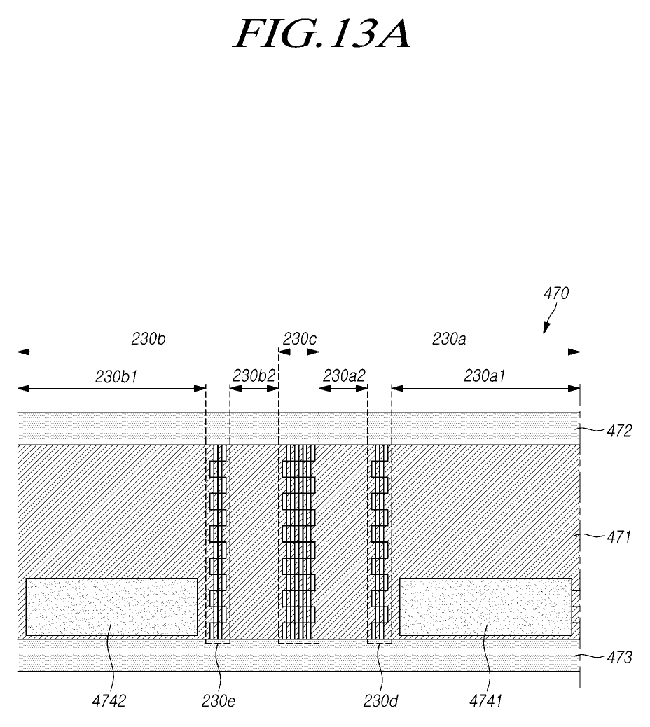

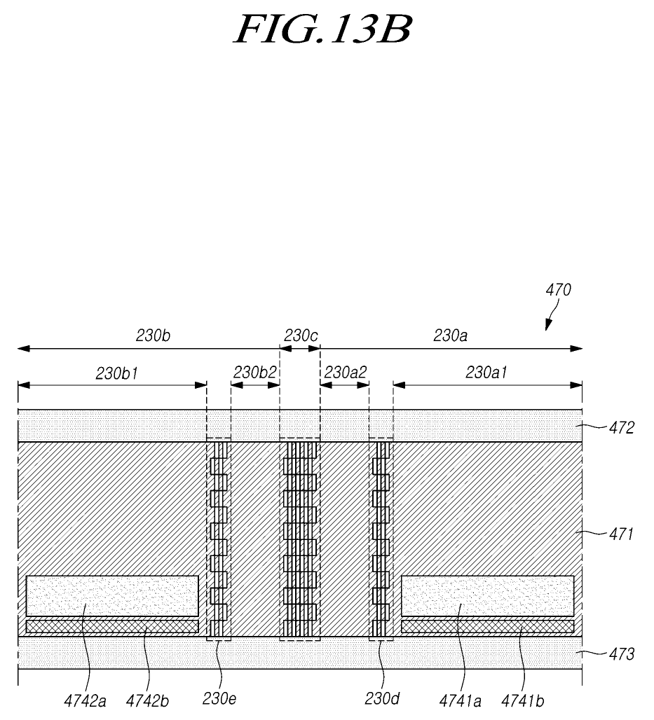

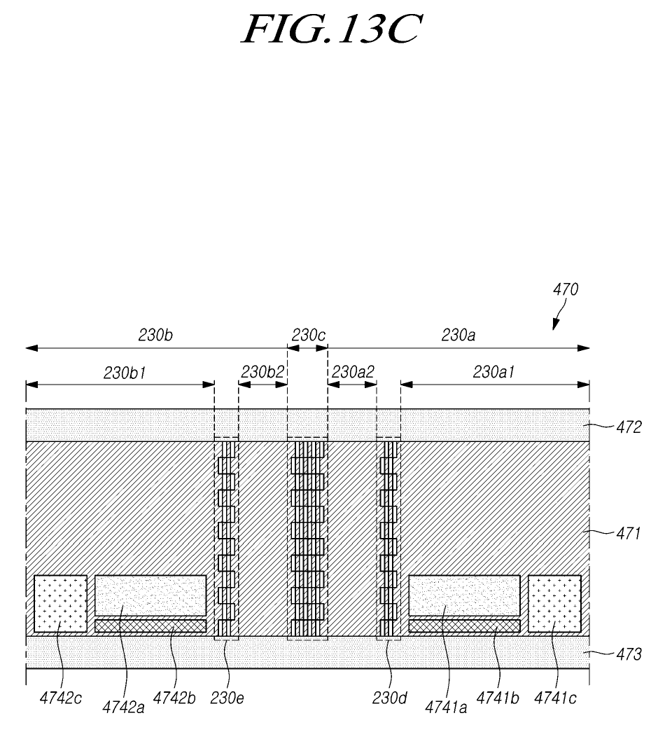

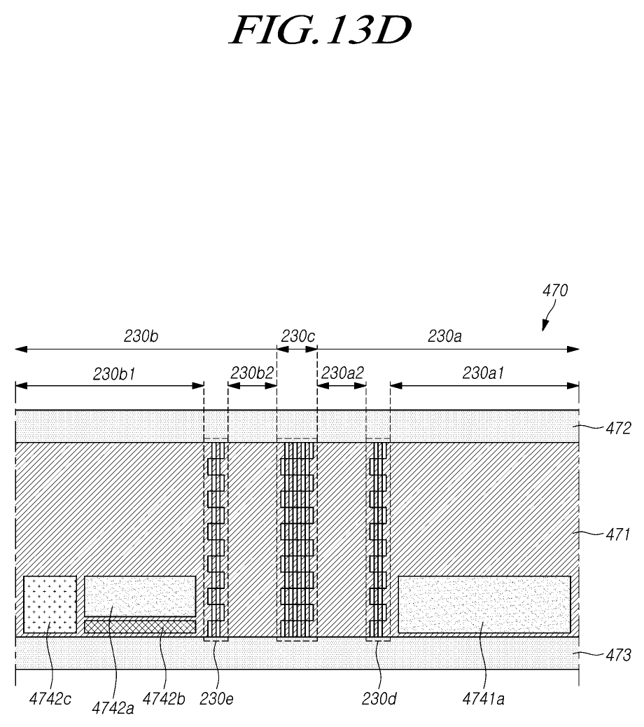

FIGS. 13A, 13B, 13C, and FIG. 13D are cross-sectional views illustrating a configuration of a shielding layer 474 inside a digitizer panel 470 according to various embodiments of the disclosure.

The digitizer panel 470 may include at least one shielding layer 474 in the flat region. The digitizer panel 470 may include a flat region including a first flat region 230a facing the first housing 210 and a second flat region 230b facing the second housing 220, and a folding region 230c facing the hinge device 320. The first flat region 230a may include a 1-1th flat region 230a1 in a direction opposite to the folding region 230c with respect to the first reverse bending section 230d, and a 1-2th flat region 230a2 between the folding region 230c and the first reverse bending section 230d. The second flat region 230b may include a 2-1th flat region 230b1 in a direction opposite to the folding region 230c with respect to the second reverse bending section 230e, and a 2-2th flat region 230b2 between the folding region 230c and the second reverse bending section 230e. The at least one shielding layer 474 may include a first shielding layer 4741 disposed in the circuit portion 471 of the 1-1th flat region 230a1, and a second shielding layer 4742 disposed in the circuit portion 471 of the 2-1th flat region 230b1. For example, the first shielding layer 4741 and the second shielding layer 4742 may include at least one of a magnetic shielding material, a conductive shielding material, and a magnet shielding material.

Referring to FIG. 13A, the digitizer panel 470 may include a first shielding layer 4741 including a magnetic shielding material and a second shielding layer 4742 including a magnetic shielding material. The first shielding layer 4741 and the second shielding layer 4742 may be formed in a layer corresponding to at least one wiring layer of the circuit portion 471. For example, the first shielding layer 4741 disposed in the circuit portion 471 of the 1-1th flat region 230a1 may include a magnetic shielding material. For example, the second shielding layer 4742 disposed in the circuit portion 471 of the 2-1th flat region 230b1 may include a magnetic shielding material.

Referring to FIG. 13B, the digitizer panel 470 may include a first shielding layer 4741 including a magnetic shielding material 4741a and a conductive shielding material 4741b, and a second shielding layer 4742 including a magnetic shielding material 4742a and a conductive shielding material 4742b. The first shielding layer 4741 and the second shielding layer 4742 may be formed in a layer corresponding to at least one wiring layer of the circuit portion 471. In the first shielding layer 4741 and the second shielding layer 4742, the conductive shielding material 4741b, 4742b may be formed on a lower portion of the magnetic shielding material 4741a, 4742a. For example, the first shielding layer 4741 disposed in the circuit portion 471 of the 1-1th flat region 230a1 may include a magnetic shielding material 4741a and a conductive shielding material 4741b formed on a lower portion of the magnetic shielding material 4741a. For example, the second shielding layer 4742 disposed in the circuit portion 471 of the 2-1th flat region 230b1 may include a magnetic shielding material 4742a and a conductive shielding material 4742b formed on a lower portion of the magnetic shielding material 4742a.

Referring to FIG. 13C, the digitizer panel 470 may include a first shielding layer 4741 including a magnetic shielding material 4741a, a conductive shielding material 4741b, and a magnet shielding material 4741c, and a second shielding layer 4742 including a magnetic shielding material 4742a, a conductive shielding material 4742b, and a magnet shielding material 4742c. The first shielding layer 4741 and the second shielding layer 4742 may be formed in a layer corresponding to at least one wiring layer of the circuit portion 471. The conductive shielding material 4741b, 4742b may be formed on a lower portion of the magnetic shielding material 4741a, 4742a. The magnet shielding material 4741c, 4742c may be formed on one side of the magnetic shielding material 4741a, 4742a. For example, the first shielding layer 4741 disposed in the circuit portion 471 of the 1-1th flat region 230a1 may include a magnetic shielding material 4741a, a conductive shielding material 4741b formed on a lower portion of the magnetic shielding material 4741a, and a magnet shielding material 4741c formed on one side of the magnetic shielding material 4741a. For example, the second shielding layer 4742 disposed in the circuit portion 471 of the 2-1th flat region 230b1 may include a magnetic shielding material 4742a, a conductive shielding material 4742b formed on a lower portion of the magnetic shielding material 4742a, and a magnet shielding material 4742c formed on one side of the magnetic shielding material 4741a.

Referring to FIG. 13D, the digitizer panel 470 may include a first shielding layer 4741 including at least one of a magnetic shielding material, a conductive shielding material, and a magnet shielding material, and a second shielding layer 4742 including at least one of a magnetic shielding material, a conductive shielding material, and a magnet shielding material. The first shielding layer 4741 and the second shielding layer 4742 may be formed in a layer corresponding to at least one wiring layer of the circuit portion 471. For example, the first shielding layer 4741 and the second shielding layer 4742 may include different configurations. For example, the first shielding layer 4741 disposed in the circuit portion 471 of the 1-1th flat region 230a1 may include a magnetic shielding material 4741a. For example, the second shielding layer 4742 disposed in the circuit portion 471 of the 2-1th flat region 230b1 may include a magnetic shielding material 4742a, a conductive shielding material 4742b formed on a lower portion of the magnetic shielding material 4742a, and a magnet shielding material 4742c formed on one side of the magnetic shielding material 4742a.

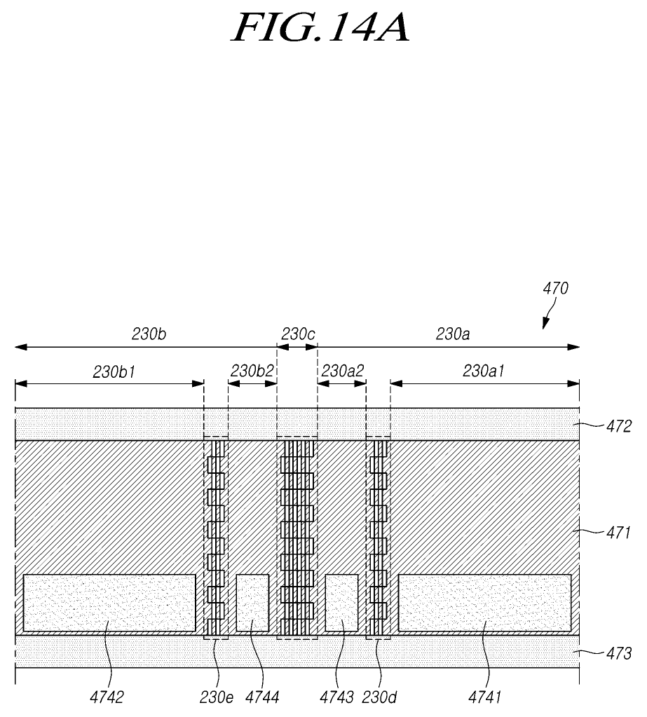

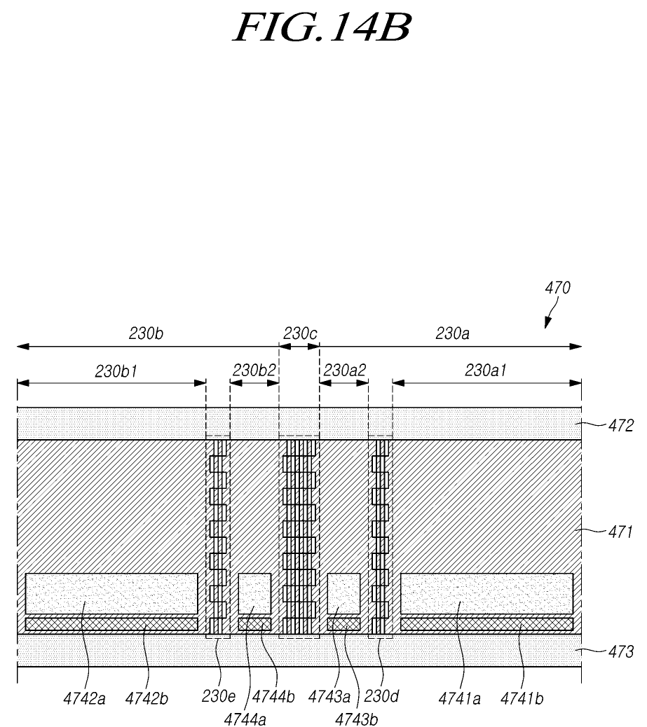

FIGS. 14A and 14B are cross-sectional views illustrating a configuration of a shielding layer 474 inside a digitizer panel 470 according to various embodiments of the disclosure.

The digitizer panel 470 may include at least one shielding layer 474 in the flat region. The digitizer panel 470 may include a flat region including a first flat region 230a facing the first housing 210 and a second flat region 230b facing the second housing 220, and a folding region 230c facing the hinge device 320. The first flat region 230a may include a 1-1th flat region 230a1 in a direction opposite to the folding region 230c with respect to the first reverse bending section 230d, and a 1-2th flat region 230a2 between the folding region 230c and the first reverse bending section 230d. The second flat region 230b may include a 2-1th flat region 230b1 in a direction opposite to the folding region 230c with respect to the second reverse bending section 230e, and a 2-2th flat region 230b2 between the folding region 230c and the second reverse bending section 230e.

In an embodiment, the at least one shielding layer 474 may include a first shielding layer 4741 disposed in the circuit portion 471 of the 1-1th flat region 230a1, and a second shielding layer 4742 disposed in the circuit portion 471 of the 2-1th flat region 230b1. Further, the at least one shielding layer 474 may further include a third shielding layer 4743 disposed in the circuit portion 471 of the 1-2th flat region 230a2, and a fourth shielding layer 4744 disposed in the circuit portion 471 of the 2-2th flat region 230b2. For example, the first shielding layer 4741, the second shielding layer 4742, the third shielding layer 4743, and the fourth shielding layer 4744 may include at least one of a magnetic shielding material, a conductive shielding material, and a magnet shielding material.

Referring to FIG. 14A, the digitizer panel 470 may include a first shielding layer 4741 including a magnetic shielding material, a second shielding layer 4742 including a magnetic shielding material, a third shielding layer 4743 including a magnetic shielding material, and a fourth shielding layer 4744 including a magnetic shielding material. The first shielding layer 4741 to the fourth shielding layer 4744 may be formed in a layer corresponding to at least one wiring layer of the circuit portion 471. For example, the first shielding layer 4741 disposed in the circuit portion 471 of the 1-1th flat region 230a1 may include a magnetic shielding material. For example, the second shielding layer 4742 disposed in the circuit portion 471 of the 2-1th flat region 230b1 may include a magnetic shielding material. The third shielding layer 4743 disposed in the circuit portion 471 of the 1-2th flat region 230a2 may include a magnetic shielding material. The fourth shielding layer 4744 disposed in the circuit portion 471 of the 2-2th flat region 230b2 may include a magnetic shielding material.

Referring to FIG. 14B, the digitizer panel 470 may include a first shielding layer 4741 including a magnetic shielding material 4741a and a conductive shielding material 4741b, a second shielding layer 4742 including a magnetic shielding material 4742a and a conductive shielding material 4742b, a third shielding layer 4743 including a magnetic shielding material 4743a and a conductive shielding material 4743b, and a fourth shielding layer 4744 including a magnetic shielding material 4744a and a conductive shielding material 4744b. The first shielding layer 4741 to the fourth shielding layer 4744 may be formed in a layer corresponding to at least one wiring layer of the circuit portion 471. In the first shielding layer 4741 to the fourth shielding layer 4744, the conductive shielding material may be formed on a lower portion of the magnetic shielding material. For example, the first shielding layer 4741 disposed in the circuit portion 471 of the 1-1th flat region 230a1 may include a magnetic shielding material 4741a and a conductive shielding material 4741b formed on a lower portion of the magnetic shielding material 4741a. For example, the second shielding layer 4742 disposed in the circuit portion 471 of the 2-1th flat region 230b1 may include a magnetic shielding material 4742a and a conductive shielding material 4742b formed on a lower portion of the magnetic shielding material 4742a. For example, the third shielding layer 4743 disposed in the circuit portion 471 of the 1-2th flat region 230a2 may include a magnetic shielding material 4743a and a conductive shielding material 4743b formed on a lower portion of the magnetic shielding material 4743a. For example, the fourth shielding layer 4744 disposed in the circuit portion 471 of the 2-2th flat region 230b2 may include a magnetic shielding material 4744a and a conductive shielding material 4744b formed on a lower portion of the magnetic shielding material 4744a.

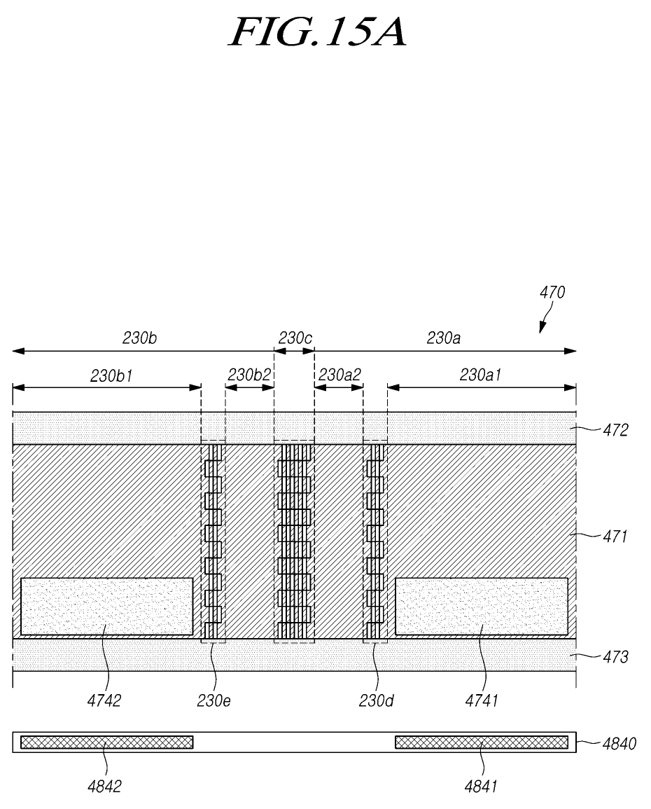

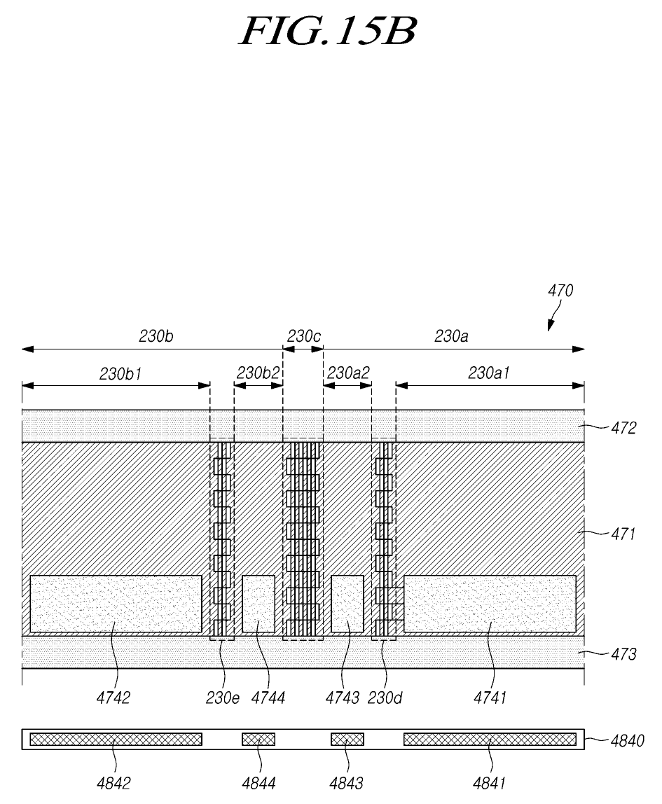

FIGS. 15A and 15B are cross-sectional views illustrating a configuration of a shielding layer 474 inside a digitizer panel 470 according to various embodiments of the disclosure.

The digitizer panel 470 may include at least one shielding layer 474 in the flat region. The digitizer panel 470 may include a flat region including a first flat region 230a facing the first housing 210 and a second flat region 230b facing the second housing 220, and a folding region 230c facing the hinge device 320. The first flat region 230a may include a 1-1th flat region 230a1 in a direction opposite to the folding region 230c with respect to the first reverse bending section 230d, and a 1-2th flat region 230a2 between the folding region 230c and the first reverse bending section 230d. The second flat region 230b may include a 2-1th flat region 230b1 in a direction opposite to the folding region 230c with respect to the second reverse bending section 230e, and a 2-2th flat region 230b2 between the folding region 230c and the second reverse bending section 230e.

Referring to FIG. 15A, the electronic device 200 may further include a shielding sheet 4840 disposed below the digitizer panel 470. For example, the digitizer panel 470 may include a first shielding layer 4741 disposed in the circuit portion 471 of the 1-1th flat region 230a1, and a second shielding layer 4742 disposed in the circuit portion 471 of the 2-1th flat region 230b1. For example, the first shielding layer 4741 and the second shielding layer 4742 may be formed in a layer corresponding to at least one wiring layer of the circuit portion 471. For example, the first shielding layer 4741 disposed in the circuit portion 471 of the 1-1th flat region 230a1 may include a magnetic shielding material. For example, the second shielding layer 4742 disposed in the circuit portion 471 of the 2-1th flat region 230b1 may include a magnetic shielding material. The shielding sheet 4840 disposed below the digitizer panel 470 may include a conductive shielding material. For example, the shielding sheet 4840 may include a conductive shielding material 4841 corresponding to the first shielding layer 4741 and a conductive shielding material 4842 corresponding to the second shielding layer 4742.

Referring to FIG. 15B, the electronic device 200 may further include a shielding sheet 4840 disposed below the digitizer panel 470. For example, the digitizer panel 470 may include a first shielding layer 4741 disposed in the circuit portion 471 of the 1-1th flat region 230a1, a second shielding layer 4742 disposed in the circuit portion 471 of the 2-1th flat region 230b1, a third shielding layer 4743 disposed in the circuit portion 471 of the 1-2th flat region 230a2, and a fourth shielding layer 4744 disposed in the circuit portion 471 of the 2-2th flat region 230b2. For example, the first shielding layer 4741 to the fourth shielding layer 4744 may be formed in a layer corresponding to at least one wiring layer of the circuit portion 471. For example, the first shielding layer 4741 disposed in the circuit portion 471 of the 1-1th flat region 230a1 may include a magnetic shielding material. For example, the second shielding layer 4742 disposed in the circuit portion 471 of the 2-1th flat region 230b1 may include a magnetic shielding material. For example, the third shielding layer 4743 disposed in the circuit portion 471 of the 1-2th flat region 230a2 may include a magnetic shielding material. For example, the fourth shielding layer 4744 disposed in the circuit portion 471 of the 2-2th flat region 230b2 may include a magnetic shielding material. The shielding sheet 4840 disposed below the digitizer panel 470 may include a conductive shielding material. For example, the shielding sheet 4840 may include a conductive shielding material 4841 corresponding to the first shielding layer 4741, a conductive shielding material 4842 corresponding to the second shielding layer 4742, a conductive shielding material 4843 corresponding to the third shielding layer 4743, and a conductive shielding material 4844 corresponding to the fourth shielding layer 4744.

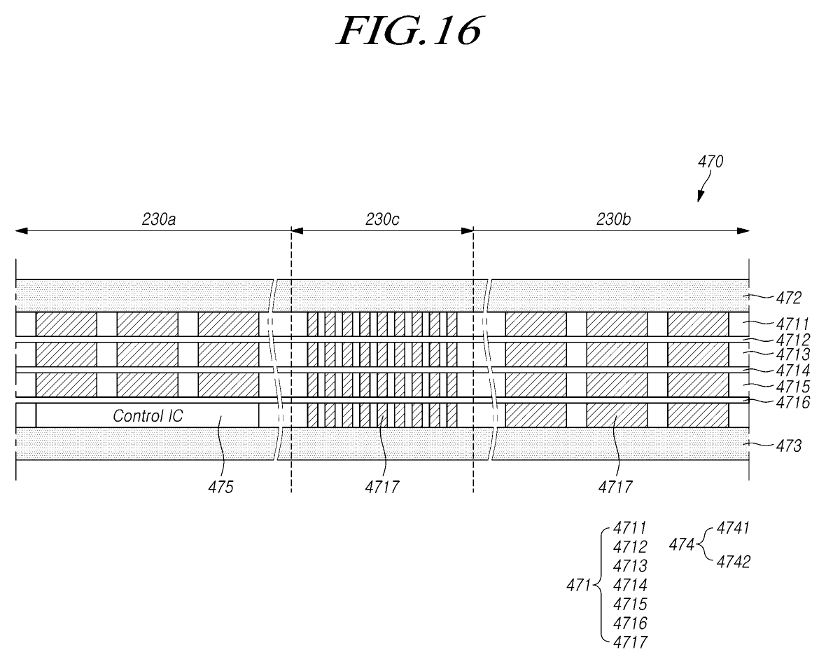

FIG. 16 is a cross-sectional view illustrating a lamination structure of a digitizer panel 470 according to an embodiment of the disclosure.

Referring to FIG. 16, the digitizer panel 470 may include a flat region including a first flat region 230a facing the first housing 210 and a second flat region 230b facing the second housing 220, and a folding region 230c facing the hinge device 320. The digitizer panel 470 may include a circuit portion 471 including at least one wiring layer and at least one insulation layer, a first shell layer 472 disposed on an upper portion of the circuit portion 471, and a second shell layer 473 disposed on a lower portion of the circuit portion 471. The at least one wiring layer may include a plurality of lines. For example, the folding region 230c of the circuit portion 471 may include N wiring layers, where N is a natural number equal to or greater than 2. For example, the flat region of the circuit portion 471 may include M wiring layers, where M is a natural number less than N, and at least one control IC 475.

According to an embodiment, as illustrated in FIG. 16, the folding region 230c of the circuit portion 471 may include four wiring layers, and the flat region of the circuit portion 471 may include three wiring layers and at least one control IC 475. For example, the at least one control IC of the flat region may be formed in the same layer as the fourth wiring layer 4717 of the folding region 230c. Meanwhile, the control IC 475 of the digitizer panel 470 of the disclosure is not limited to FIG. 16, and the control IC of the disclosure may be variously disposed inside the digitizer panel 470. For example, the control IC 475 may be disposed in at least one of the first flat region 230a and the second flat region 230b. For example, the control IC 475 may be formed in a layer corresponding to the third wiring layer 4715 and the fourth wiring layer 4717 of the folding region 230c.

As described above, according to various embodiments of the disclosure, the foldable electronic device 200 and the method for manufacturing the same according to the disclosure may minimize circuit disconnection of the digitizer panel 470 in the folding region 230c during folding by including a digitizer panel 470 including a high-rigidity shell layer and a bending pattern 4731. Further, the foldable electronic device 200 and the method for manufacturing the same according to the disclosure may prevent corrosion of the shielding layer 474 and may enhance flatness of the display by including a digitizer panel 470 incorporating at least one shielding layer 474. However, since this has been described above, no duplicate description is given.

A foldable electronic device 200 according to embodiments of the disclosure may include a first housing, a second housing, a hinge device rotatably connecting the first housing and the second housing, a flexible display 230 disposed across the first housing and the second housing and including a folding region 230c, and a digitizer panel 470 disposed below the flexible display 230 and including a bending pattern 4731 including a plurality of openings disposed at a designated interval. The digitizer panel 470 may include a circuit portion 471 including at least one wiring layer and at least one insulation layer, a first shell layer 472 disposed on an upper portion of the circuit portion 471, and a second shell layer 473 disposed on a lower portion of the circuit portion 471.

In an embodiment, the digitizer panel 470 may include a flat region including a first flat region 230a facing the first housing and a second flat region 230b facing the second housing, and the folding region 230c. The folding region 230c of the circuit portion 471 may include N wiring layers, where N is a natural number equal to or greater than 2. The flat region of the circuit portion 471 may include M wiring layers, where M is a natural number less than N, and at least one shielding layer 474.

In an embodiment, the first shell layer 472 and the second shell layer 473 may include at least one of a carbon fiber reinforced plastics (CFRP) sheet and a glass fiber reinforced plastics (GFRP) sheet.

In an embodiment, the folding region 230c of the digitizer panel 470 may include a bending section. The bending section may include the bending pattern 4731 including the plurality of openings having a first length along a folding axis, a first width W1 smaller than the first length, and disposed at a first interval.

In an embodiment, the first length of the plurality of openings may have a length of 15 times to 30 times the first interval. The first width W1 of the plurality of openings may have a length of 1.2 times to 1.5 times the first interval.

In an embodiment, the flat region of the digitizer panel 470 may include a reverse bending section. The reverse bending section may include the bending pattern 4731 including the plurality of openings having a second length along the folding axis, a second width smaller than the second length, and disposed at a second interval.

In an embodiment, the folding region 230c of the circuit portion 471 may include four wiring layers. The flat region of the circuit portion 471 may include three wiring layers and the at least one shielding layer 474.

In an embodiment, the folding region 230c of the circuit portion 471 may include four wiring layers. The flat region of the circuit portion 471 may include two wiring layers and the at least one shielding layer 474.

In an embodiment, the folding region 230c of the circuit portion 471 may include three wiring layers. The flat region of the circuit portion 471 may include two wiring layers and the at least one shielding layer 474.

In an embodiment, the at least one shielding layer 474 may include a plurality of filling holes FH disposed at a constant interval and into which resin is introduced. The filling hole FH may have a diameter of between 0.1 mm and 5 mm.

In an embodiment, the first flat region 230a may include a 1-1th flat region 230a1 in a direction opposite to the folding region 230c with respect to a first reverse bending section 230d, and a 1-2th flat region 230a2 between the folding region 230c and the first reverse bending section 230d. The second flat region 230b may include a 2-1th flat region 230b1 in a direction opposite to the folding region 230c with respect to a second reverse bending section 230e, and a 2-2th flat region 230b2 between the folding region 230c and the second reverse bending section 230e.

In an embodiment, the at least one shielding layer 474 may include a first shielding layer 4741 disposed in the circuit portion 471 of the 1-1th flat region 230a1, and a second shielding layer 4742 disposed in the circuit portion 471 of the 2-1th flat region 230b1.

In an embodiment, the first shielding layer 4741 and the second shielding layer 4742 may include at least one of a magnetic shielding material, a conductive shielding material, and a magnet shielding material.

In an embodiment, the at least one shielding layer 474 may further include a third shielding layer 4743 disposed in the circuit portion 471 of the 1-2th flat region 230a2, and a fourth shielding layer 4744 disposed in the circuit portion 471 of the 2-2th flat region 230b2.

In an embodiment, the third shielding layer 4743 and the fourth shielding layer 4744 may include at least one of a magnetic shielding material, a conductive shielding material, and a magnet shielding material.

In an embodiment, the foldable electronic device may further include a shielding sheet 4840 disposed below the digitizer panel 470. The at least one shielding layer 474 may include a magnetic shielding material. The shielding sheet may include a conductive shielding material.

In an embodiment, the digitizer panel 470 may include a flat region including a first flat region 230a facing the first housing and a second flat region 230b facing the second housing, and the folding region 230c. The folding region 230c of the circuit portion 471 may include N wiring layers, where N is a natural number equal to or greater than 2. The flat region 230a, 230b of the circuit portion 471 may include M wiring layers, where M is a natural number less than N, and at least one control IC 475.

A method for manufacturing a foldable electronic device 200 according to embodiments of the disclosure may include forming a flexible display 230 disposed across a first housing and a second housing and including a folding region 230c, and forming a digitizer panel 470 disposed below the flexible display 230. Forming the digitizer panel 470 may include forming a circuit portion 471 including at least one wiring layer and at least one insulation layer, forming a first shell layer 472 disposed on an upper portion of the circuit portion 471 and a second shell layer 473 disposed on a lower portion of the circuit portion 471, and forming a bending pattern 4731 including a plurality of openings disposed at a designated interval.

In an embodiment, the digitizer panel 470 may include a flat region including a first flat region 230a facing the first housing and a second flat region 230b facing the second housing, and the folding region 230c. Forming the circuit portion 471 may include forming N wiring layers, where N is a natural number equal to or greater than 2, in the folding region 230c of the circuit portion 471, and forming M wiring layers, where M is a natural number less than N, and at least one shielding layer 474 in the flat region of the circuit portion 471.

In an embodiment, the first shell layer 472 and the second shell layer 473 may include at least one of a carbon fiber reinforced plastics (CFRP) sheet and a glass fiber reinforced plastics (GFRP) sheet.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A foldable electronic device comprising:
a first housing;
a second housing;
a hinge device rotatably connecting the first housing and the second housing;
a flexible display disposed across the first housing and the second housing; and
a digitizer panel disposed below the flexible display, the digitizer panel including a bending pattern including a plurality of openings disposed at a designated interval and a folding region,
wherein the digitizer panel further includes:
a circuit portion including at least one wiring layer and at least one insulation layer;
a first shell layer disposed on an upper portion of the circuit portion; and
a second shell layer disposed on a lower portion of the circuit portion.

2. The foldable electronic device of claim 1,
wherein the digitizer panel further includes a first flat region facing the first housing and a second flat region facing the second housing,
wherein the folding region of the circuit portion includes N wiring layers, wherein N is a natural number equal to or greater than two, and
wherein the flat region of the circuit portion includes M wiring layers and at least one shielding layer, wherein M is a natural number less than N.

3. The foldable electronic device of claim 2, wherein the first shell layer and the second shell layer include at least one of a carbon fiber reinforced plastics sheet or a glass fiber reinforced plastics sheet.

4. The foldable electronic device of claim 2,
wherein the folding region of the digitizer panel includes a bending section, and
wherein the bending section includes the bending pattern including the plurality of openings, the plurality of openings in the bending section including a first length along a folding axis and a first width smaller than the first length, the plurality of openings being disposed at a first interval.

5. The foldable electronic device of claim 4,
wherein the first length of the plurality of openings is in a range of fifteen times the first interval to thirty times the first interval, and
wherein the first width of the plurality of openings is in a range of 1.2 times the first interval to 1.5 times the first interval.

6. The foldable electronic device of claim 4,
wherein the flat region of the digitizer panel includes a reverse bending section, and
wherein the reverse bending section includes the bending pattern including the plurality of openings, the plurality of openings in the reverse bending section including a second length along the folding axis and a second width smaller than the second length, the plurality of openings being disposed at a second interval.

7. The foldable electronic device of claim 2,
wherein the folding region of the circuit portion includes four layers from among the N wiring layers, and
wherein the flat region of the circuit portion includes three layers from among the M wiring layers and the at least one shielding layer.

8. The foldable electronic device of claim 2,
wherein the folding region of the circuit portion includes four layers from among the N wiring layers, and
wherein the flat region of the circuit portion includes two layers from among the M wiring layers and the at least one shielding layer.

9. The foldable electronic device of claim 2,
wherein the folding region of the circuit portion includes three layers from among the N wiring layers, and
wherein the flat region of the circuit portion includes two layers from among the M wiring layers and the at least one shielding layer.

10. The foldable electronic device of claim 2,
wherein the at least one shielding layer includes a plurality of filling holes disposed at a constant interval, the plurality of filling holes being configured to receive resin, and
wherein each of the plurality of filling holes has a diameter of between 0.1 mm and 5 mm.

11. The foldable electronic device of claim 2,
wherein the first flat region includes a 1-1th flat region in a direction opposite to the folding region with respect to a first reverse bending section, and a 1-2th flat region between the folding region and the first reverse bending section, and
wherein the second flat region includes a 2-1th flat region in a direction opposite to the folding region with respect to a second reverse bending section, and a 2-2th flat region between the folding region and the second reverse bending section.

12. The foldable electronic device of claim 11, wherein the at least one shielding layer includes:
a first shielding layer disposed in the circuit portion of the 1-1th flat region; and
a second shielding layer disposed in the circuit portion of the 2-1th flat region, and
wherein the first shielding layer and the second shielding layer include at least one of a magnetic shielding material, a conductive shielding material, or a magnet shielding material.

13. The foldable electronic device of claim 12, wherein the at least one shielding layer further includes:
a third shielding layer disposed in the circuit portion of the 1-2th flat region; and
a fourth shielding layer disposed in the circuit portion of the 2-2th flat region, and
wherein the third shielding layer and the fourth shielding layer include at least one of a magnetic shielding material, a conductive shielding material, or a magnet shielding material.

14. The foldable electronic device of claim 12, further comprising a shielding sheet disposed below the digitizer panel,
wherein the at least one shielding layer includes a magnetic shielding material, and
wherein the shielding sheet includes a conductive shielding material.

15. A method for manufacturing a foldable electronic device, the method comprising:
forming a flexible display disposed across a first housing and a second housing; and
forming a digitizer panel disposed below the flexible display, the digitizer panel including a folding region,
wherein the forming of the digitizer panel includes:
forming a circuit portion including at least one wiring layer and at least one insulation layer;
forming a first shell layer disposed on an upper portion of the circuit portion and a second shell layer disposed on a lower portion of the circuit portion; and
forming a bending pattern including a plurality of openings disposed at a designated interval.

16. The method of claim 15,
wherein the forming of the digitizer panel further includes forming a first flat region facing the first housing and a second flat region facing the second housing,
wherein the folding region of the circuit portion includes N wiring layers, wherein N is a natural number equal to or greater than two, and
wherein the flat region of the circuit portion includes M wiring layers and at least one shielding layer, wherein M is a natural number less than N.

17. The method of claim 16,
wherein the folding region of the digitizer panel includes a bending section,
wherein the bending section includes the bending pattern including the plurality of openings,
wherein, in the bending section, the forming of the bending pattern includes forming the plurality of openings with a first length along a folding axis and a first width smaller than the first length, and
wherein, in the bending section, the forming of the bending pattern further includes forming the plurality of openings at a first interval.

18. The method of claim 17,
wherein the first length of the plurality of openings is in a range of fifteen times the first interval to thirty times the first interval, and
wherein the first width of the plurality of openings is in a range of 1.2 times the first interval to 1.5 times the first interval.

19. The method of claim 16,
wherein the forming the circuit portion includes forming of the folding region of the circuit portion and forming of the flat region of the circuit portion,
wherein the forming of the folding region of the circuit portion includes forming four layers of the at least one wiring layer, and
wherein the forming of the flat region of the circuit portion includes forming three layers from among the at least one wiring layer and the at least one shielding layer.

20. The method of claim 16,
wherein the forming the circuit portion includes forming of the folding region of the circuit portion and forming of the flat region of the circuit portion,
wherein the forming of the folding region of the circuit portion includes forming three layers of the at least one wiring layer, and
wherein the forming of the flat region of the circuit portion includes forming two layers from among the at least one wiring layer and the at least one shielding layer.
